(19) United States
(12) Patent Application Publication
(10) Pub. No.: US 2025/0143121 A1
(43) Pub. Date: May 1, 2025

(54) DISPLAY DEVICE

(71) Applicant: Samsung Display Co., LTD., Yongin-si (KR)

(72) Inventors: Dong Hwan SHIM, Yongin-si (KR); Kwang Woo PARK, Yongin-si (KR); Eon Joo LEE, Yongin-si (KR); Jin Yong LEE, Yongin-si (KR); Cheol JANG, Yongin-si (KR); Yong Seon JO, Yongin-si (KR)

(21) Appl. No.: 18/889,210

(22) Filed: Sep. 18, 2024

(30) Foreign Application Priority Data
Oct. 26, 2023 (KR) 10-2023-0144552

(51) Int. Cl. H10K 59/131; H10K 59/124

(52) U.S. Cl. CPC H10K 59/131; H10K 59/124

(57) ABSTRACT

A display device includes a first sub-display area and a second sub-display area that are adjacent each other, and a main display area around the first and second sub-display areas, a plurality of pixel electrodes in the main display area and spaced from one another, a plurality of first subpixel electrodes in the first sub-display area and spaced from one another, a plurality of first copy pixel electrodes in the first sub-display area and connected to the first subpixel electrodes through first bridge electrodes, a plurality of planarization patterns in the second sub-display area, a plurality of second subpixel electrodes and a plurality of second copy pixel electrodes in the second sub-display area that overlaps the planarization patterns, and a plurality of second bridge electrodes that overlaps the second subpixel electrodes or the second copy pixel electrodes.

### CROSS-REFERENCE TO RELATED APPLICATION

The present application claims priority to and the benefit of Korean Patent Application No. 10-2023-0144552, filed on Oct. 26, 2023 in the Korean Intellectual Property Office, the entire disclosure of which is incorporated by reference herein.

### BACKGROUND

### 1. Field

The present disclosure relates to a display device.

### 2. Description of the Related Art

With the advancement of the information society, the demand for display devices for displaying images has increased in various forms. For example, display devices are being applied to various electronic devices such as smartphones, digital cameras, laptop computers, navigation devices, and smart televisions (TVs). Display devices can be flat panel display devices such as liquid crystal display (LCD) devices, field-emission display (FED) devices, and organic light-emitting display devices. Among these flat panel display devices, light-emitting display devices can display images without backlight units that provide light to the display panels, by including light-emitting elements that allow pixels of the display panels to emit light on their own.

Display devices may include pixels emitting light, scan lines, data lines, and power lines for driving the pixels, a scan driving unit outputting scan signals to the scan lines, and a display driving unit outputting data voltages to the data lines.

### SUMMARY

Aspects and features of embodiments of the present disclosure provide a display device including bridge patterns, which are disposed between adjacent display areas.

Aspects and features of embodiments of the present disclosure also provide a display device including pixels with different structures and capable of securing flatness for pixel electrodes of light-emitting elements included in pixels connected by bridge patterns.

However, aspects and features of embodiments of the present disclosure are not restricted to those set forth herein. The above and other aspects and features of embodiments of the present disclosure will become more apparent to one of ordinary skill in the art to which the present disclosure pertains by referencing the detailed description of the present disclosure given below.

According to one or more embodiments of the present disclosure, a display device includes a first sub-display area and a second sub-display area that are adjacent each other, and a main display area around the first and second sub-display areas, a plurality of pixel electrodes in the main display area and spaced from one another, a plurality of first subpixel electrodes in the first sub-display area and spaced from one another, a plurality of first copy pixel electrodes in the first sub-display area and connected to the first subpixel electrodes through first bridge electrodes, a plurality of planarization patterns in the second sub-display area, a plurality of second subpixel electrodes and a plurality of second copy pixel electrodes in the second sub-display area that overlaps the planarization patterns, and a plurality of second bridge electrodes that overlaps the second subpixel electrodes or the second copy pixel electrodes.

The first subpixel electrodes, the first copy pixel electrodes, and the first bridge electrodes, in the first sub-display area, may be integrated together.

The second bridge electrodes may overlap different planarization patterns.

Each of the second bridge electrodes may be in direct contact with one of the planarization patterns.

In a plan view, the planarization patterns may have an area that is larger than both the second subpixel electrodes and the second copy pixel electrodes.

The planarization patterns may include first planarization patterns and second planarization patterns that are located directly on the first planarization patterns, and the second planarization patterns may cover outer surfaces of the first planarization patterns.

The display device may further include a plurality of first bridge patterns extending in one direction in the second sub-display area, a plurality of second bridge patterns extending in the one direction in the first sub-display area, and a plurality of contact patterns overlapping the first bridge patterns and the second bridge patterns, near a boundary between the first and second sub-display areas.

The display device may further include a plurality of first subpixel circuits and a plurality of second subpixel circuits in the main display area, wherein the first subpixel electrodes may overlap the first subpixel circuits, and at least some of the first copy pixel electrodes may overlap the second subpixel circuits.

Each of the second bridge patterns may be electrically connected to one of the second subpixel circuits.

Each of the first bridge patterns may be connected to one of the planarization patterns.

Each of the second bridge patterns may overlap the first subpixel electrodes, but be not connected to the first subpixel electrodes.

The display device may further include a first insulating layer in the main display area and the first sub-display area and including an organic insulating material, and an interlayer insulating layer on the first insulating layer, in the main display area and the first and second sub-display areas, wherein the first insulating layer do not overlap the planarization patterns, the second subpixel electrodes, and the second copy pixel electrodes.

In the second sub-display area, the interlayer insulating layer may overlap the planarization patterns, the second subpixel electrodes, and the second copy pixel electrodes.

The first insulating layer may overlap the contact patterns.

The display device may further include a first pixel-defining film in the main display area and the first sub-display area and having a plurality of openings that overlap the pixel electrodes, the first subpixel electrodes, and the first copy pixel electrodes, and a second pixel-defining film in the second sub-display area covering edges of the second subpixel electrodes and edges of the second copy pixel electrodes.

According to one or more embodiments of the present disclosure, a display device includes a substrate having a first sub-display area and a second sub-display area that are adjacent each other, and a main display area around the first and second sub-display areas, a semiconductor layer including a plurality of active layers on the substrate, in the main display area, and the first sub-display area, and a plurality of first bridge patterns in the second sub-display area, a first insulating layer on the semiconductor layer, a first conductive layer including a plurality of first connection electrodes on the first insulating layer, in the first sub-display area, and a plurality of first planarization patterns in the second sub-display area, a second insulating layer on the first conductive layer, the second insulating layer not being in the second sub-display area, a second conductive layer including a plurality of second connection electrodes on the second insulating layer, in the first sub-display area, and a plurality of second planarization patterns on the first planarization patterns, in the second sub-display area, an interlayer insulating layer on the second conductive layer, a plurality of second bridge patterns on the interlayer insulating layer, in the first sub-display area, and a plurality of bridge electrodes on the second planarization patterns, in the second sub-display area, a third insulating layer on the interlayer insulating layer and the second bridge patterns, in the main display area and the first sub-display area, a plurality of pixel electrodes on the third insulating layer, in the main display area, a plurality of first subpixel electrodes and a plurality of first copy pixel electrodes on the third insulating layer, in the first sub-display area, and a plurality of second subpixel electrodes and a plurality of second copy pixel electrodes on the bridge electrodes, in the second sub-display area.

The bridge electrodes may include first portions that are on different second planarization patterns and second portions that connect the first portions, and the second subpixel electrodes and the second copy pixel electrodes may be respectively on different first portions of the bridge electrodes.

A width of the second planarization patterns may be greater than widths of the second subpixel electrodes and the second copy pixel electrodes.

The first connection electrodes and the second connection electrodes may be electrically connected to the first subpixel electrodes, and the first copy pixel electrodes may be integrated with the first subpixel electrodes.

The semiconductor layer may include a first semiconductor layer including a first active layer, and a second semiconductor layer including a second active layer and located between the first semiconductor layer and the first insulating layer, and the first bridge patterns.

According to the aforementioned and other embodiments of the present disclosure, the display device can ensure the transmittance of a sub-display area where an optical device is located, and can secure flatness for pixel electrodes even if an organic insulating layer is not provided.

It should be noted that the effects, aspects, and features of embodiments of the present disclosure are not limited to those described above, and other effects, aspects, and features of embodiments of the present disclosure will be apparent from the following description.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of a display device according to one or more embodiments of the present disclosure;

FIG. 2 is a plan view of the display device of FIG. 1;

FIG. 3 is a cross-sectional view taken along the line A-A′ of FIG. 2;

FIG. 4 is a plan view of a display panel according to one or more embodiments of the present disclosure;

FIG. 5 is a circuit diagram of a subpixel according to one or more embodiments of the present disclosure;

FIG. 6 is a plan view illustrating the arrangement of pixels in a main display area and a sub-display area of the display device of FIG. 1;

FIG. 7 is a plan view illustrating the arrangement of pixel electrodes included in subpixels in the main display area of FIG. 6;

FIG. 8 is a plan view illustrating the arrangement of pixel electrodes included in subpixels in the sub-display area of FIG. 6;

FIG. 9 is a cross-sectional view illustrating a main display area of the display device of FIG. 1;

FIGS. 10 and 11 are cross-sectional views illustrating sub-display areas of the display device of FIG. 1;

FIGS. 12 through 19 are plan views illustrating a plurality of layers disposed in the sub-display area of the display device of FIG. 1; and

FIG. 20 is a cross-sectional view illustrating a sub-display area of a display device according to one or more embodiments of the present disclosure.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to embodiments set forth herein. Rather, these embodiments are provided so that the present disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Embodiments of the present disclosure will be described with reference to the attached drawings.

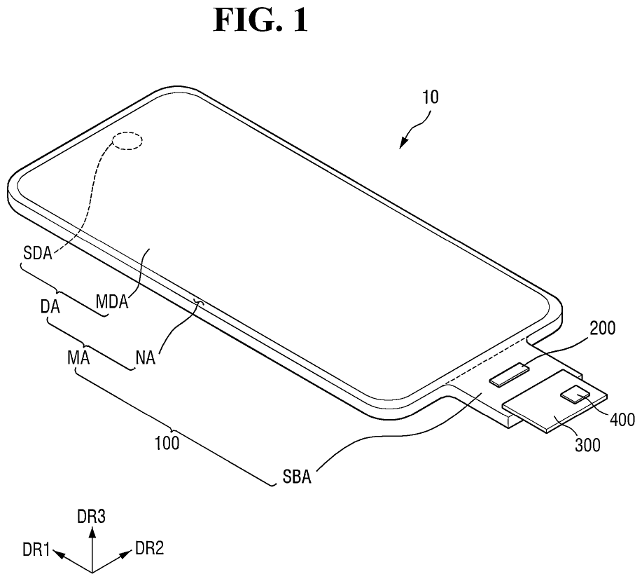

FIG. 1 is a perspective view of a display device according to one or more embodiments of the present disclosure.

Referring to FIG. 1, a display device 10 is a device for displaying videos and/or still images and may be used as a display screen for portable electronic devices such as mobile phones, smartphones, tablet personal computers (PCs), smartwatches, watch phones, mobile communication terminals, electronic notebooks, e-book readers, portable multimedia players (PMPs), navigation devices, or ultra mobile PCs (UMPCs), as well as various other products such as televisions, laptops, monitors, advertising boards, and/or Internet of Things (IoT) devices.

In one or more embodiments, the display device 10 may be a light-emitting display device, such as an organic light-emitting display device including organic light-emitting diodes (OLEDs), a quantum dot light-emitting display device including quantum dot emitting layers, an inorganic light-emitting display device including inorganic semiconductors, or an ultra-small light-emitting display device using micro- or nano-light-emitting diodes (microLEDs or nanoLEDs). The display device 10 will hereinafter be described as being, for example, an organic light-emitting display device.

In one or more embodiments, the display device 10 may be formed to be flat. For example, the display device 10 may be formed to be substantially flat in a plane defined by first and second directions DR1 and DR2 and may have a suitable thickness (e.g., a predetermined thickness or height) in a third direction DR3. In one or more embodiments, the display device 10 may be curved at least in part in, for example, an edge area. Moreover, the display device 10 may be formed to be curved or flexible such as bendable, foldable, and/or rollable.

In one or more embodiments, based on an image display surface of the display device 10, the first direction DR1 may be a lengthwise direction, a column direction, or a vertical direction, the second direction DR2 may be a direction crossing the first direction DR1, for example, a widthwise direction, a row direction, or a horizontal direction, and the third direction DR3 may be the thickness or height direction of the display device 10.

The display device 10 may include a display panel 100, a driving unit 200, and a circuit board 300.

The display panel 100 may have a main area MA, which includes a display area DA where an image is displayed, and a subarea SBA, which is positioned on one side of the main area MA.

The main area MA may include the display area DA and a non-display area NA, which is around (e.g., surrounds) the display area DA along an edge or a periphery of the display area DA. The display area DA may be positioned in the middle of the main area MA and may occupy most of the main area MA. The non-display area NA may be positioned at the edges of the main area MA and may adjoin the subarea SBA.

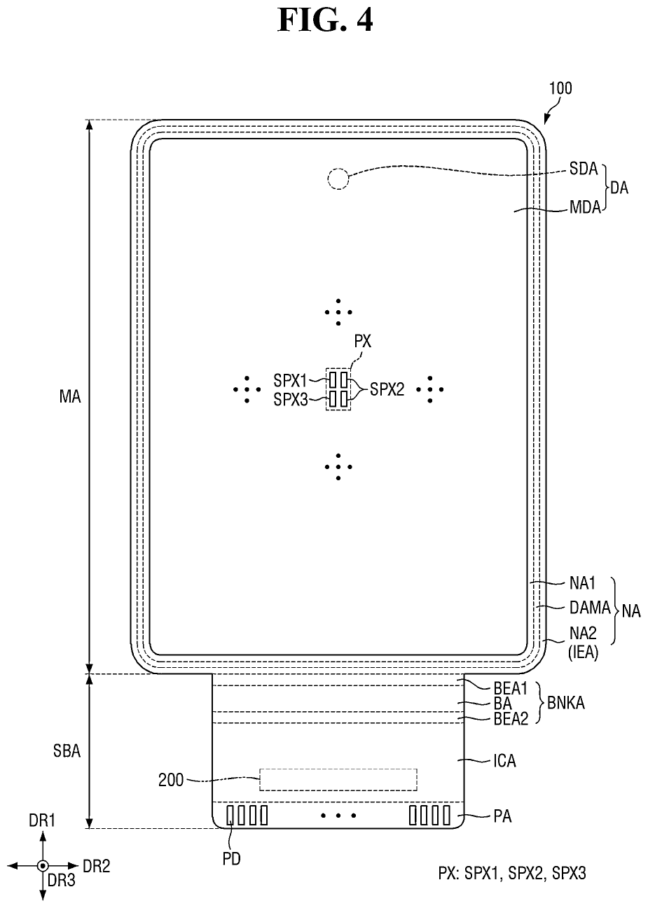

The display area DA may be an area where pixels (“PX” of FIG. 4) are arranged and an image is displayed by the pixels PX. In one or more embodiments, sensing patterns (e.g., touch electrodes) may be further provided in the display area DA for detecting input such as touch input, and the display area DA may include a sensing area that detects touch input via the sensing patterns.

In one or more embodiments, the display area DA may have long sides in the first direction DR1 and short sides in the second direction DR2 and may be formed as a plane with a substantially rectangular shape. The corners where the long sides and short sides of the display area DA meet may be rounded or formed at right angles. The shape of the display area DA may vary. Alternatively, the display area DA may be formed in a non-rectangular polygonal shape, a circular shape, and/or an elliptical shape.

The display area DA may include a main display area MDA and a sub-display area SDA. The sub-display area SDA, which is an area where components for adding various functionalities to the display device 10 are disposed, may correspond to a component area.

The non-display area NA may be positioned immediately around the display area DA. The non-display area NA may surround the display area DA. Embedded circuits may be disposed in the non-display area NA. For example, embedded circuits, including scan driving circuits, may be positioned in the non-display area NA, which is positioned on one side (e.g., the left or right side) or both sides of the display area DA.

The subarea SBA may be positioned on one side of the main area MA. For example, the subarea SBA may be an area that protrudes in the first direction DR1 from one side of the main area MA. For example, the subarea SBA may protrude in the first direction DR1 from the bottom of the main area MA. In one or more embodiments, the subarea SBA might have a narrower width than the main area MA. For example, the subarea SBA may have a smaller width than the main area MA in the second direction DR2.

Wires and pads may be disposed in the subarea SBA. For example, wires and pads connected to the pixels PX and/or the embedded circuits, which are positioned in the main area MA, and wires and pads connected to the driving unit 200 and/or the circuit board 300, which is positioned in the subarea SBA, may be disposed in the subarea SBA. The term “connect” or “connection” may encompass both electrical connection and/or physical connection.

In one or more embodiments, the driving unit 200 (e.g., display driving circuitry) may be mounted in the subarea SBA. The circuit board 300 may be disposed on a part of the subarea SBA.

The driving unit 200 may include a data driving circuit for operating the pixels PX. In one or more embodiments, the driving unit 200 may be formed as an integrated circuit (IC) chip and may be disposed in the subarea SBA. In one or more embodiments, the driving unit 200 may be disposed on the circuit board 300 in the subarea SBA or on another circuit board connected to the display panel 100 through the circuit board 300.

The circuit board 300 may be disposed on a part of the subarea SBA. For example, the circuit board 300 may be bonded on pads positioned on a portion (e.g., the bottom edge) of the subarea SBA, and may supply or transfer power voltages and driving signals to the display panel 100. For example, the circuit board 300 may supply input image data (e.g., digital image data), driving signals including timing signals, and driving voltages to the display panel 100. The circuit board 300 may be a flexible film such as a flexible printed circuit board (FPCB), a printed circuit board (PCB), or a chip-on-film (COF), but the present disclosure is not limited thereto.

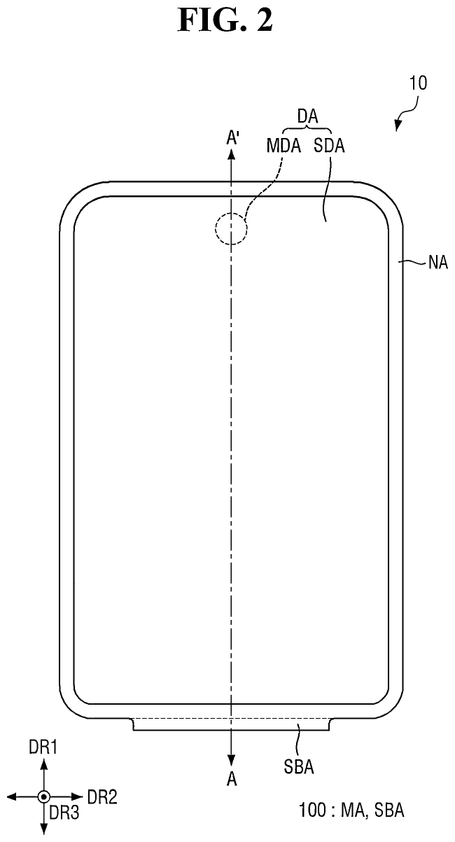

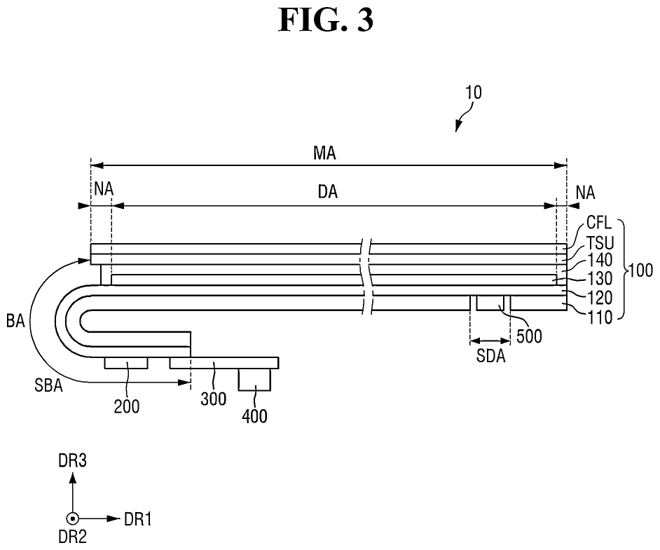

FIG. 2 is a plan view of the display device of FIG. 1. FIG. 3 is a cross-sectional view taken along the line A-A′ of FIG. 2.

FIG. 1 illustrates the display device 10 in an unfolded, non-bent state, and FIGS. 2 and 3 illustrate the display device 10 in a bent state in the subarea SBA. FIG. 1 illustrates the subarea SBA being spread in parallel to the main area MA, and FIGS. 2 and 3 illustrate part of the subarea SBA in a bent state.

Referring to FIGS. 2 and 3, the display panel 100 may include a substrate 110, which includes the main area MA and the subarea SBA, and a circuit layer 120, a light-emitting element layer 130, an encapsulation layer 140, a touch sensing layer TSU, and a color filter layer CFL, which are sequentially disposed on the substrate 110. The circuit layer 120 may be positioned in both the main area MA and the subarea SBA on the substrate 110. The light-emitting element layer 130 and the encapsulation layer 140 may be disposed on parts of the substrate 110 and the circuit layer 120. For example, the light-emitting element layer 130 and the encapsulation layer 140 may be positioned in the main area MA.

In one or more embodiments, the display device 10 may further include additional components disposed on the display panel 100. For example, the display device 10 may further include at least one of a polarization layer and a protective layer (e.g., a window), which are disposed on the encapsulation layer 140. The polarization layer and/or the protective layer may be integrated with the display panel 100 or may be produced separately from the display panel 100 and then attached to the display panel 100 via an adhesive layer.

The substrate 110 may include an insulating material such as a polymer resin. For example, the substrate 110 may be formed of polyimide or another insulating material. The substrate 110 may be a flexible substrate that is bendable, foldable, and/or rollable. Alternatively, the substrate 110 may include an insulating material such as glass.

The circuit layer 120 may include pixel circuits and wires. For example, the circuit layer 120 may include circuit elements (e.g., pixel transistors and/or capacitors) that constitute the pixel circuits of the pixels PX and wires that are connected to the pixels PX. In one or more embodiments, the circuit layer 120 may further include circuit elements that constitute embedded circuits such as scan driving circuits and wires that are connected to the embedded circuits.

The light-emitting element layer 130 may include light-emitting elements, which are disposed in the light-emitting areas of the pixels PX. For example, each of the pixels PX may include at least one light-emitting element and a pixel circuit connected to the light-emitting element. Each of the pixels PX may be positioned in a pixel area, which includes a light-emitting area where a light-emitting element is disposed and a pixel circuit region where a pixel circuit is disposed. The light-emitting area and the pixel circuit region of each of the pixels PX may overlap with each other, but the present disclosure is not limited thereto.

The circuit layer 120 and the light-emitting element layer 130 have been described as being separate layers, but the present disclosure is not limited thereto. Alternatively, the circuit layer 120 and the light-emitting element layer 130 may be integrated together.

The encapsulation layer 140 covers the light-emitting element layer 130 and may extend to the non-display area NA to be in contact with the circuit layer 120. In one or more embodiments, the encapsulation layer 140 may have a multilayer structure including at least two overlapping inorganic encapsulation films and at least one organic encapsulation film interposed between the overlapping inorganic encapsulation films.

The touch sensing layer TSU may be disposed on the encapsulation layer 140. The touch sensing layer TSU may include a plurality of touch electrodes, which are for detecting a user's touch in a capacitive manner, and touch lines, which connect the touch electrodes to a touch driving unit 400. For example, the touch sensing layer TSU may sense the user's touch using a mutual capacitance method or a self-capacitance method.

In one or more embodiments, the touch sensing layer TSU may be disposed on a separate substrate disposed on the display panel 100. In this embodiment, the separate substrate may be a base member encapsulating the display panel 100.

The touch electrodes of the touch sensing layer TSU may be disposed in a touch sensor area overlapping with the display area DA. The touch lines of the touch sensing layer TSU may be disposed in a touch peripheral area overlapping with the non-display area NA.

In one or more embodiments, the display device 10 may further include an optical device 500. The optical device 500 may be disposed in the sub-display area SDA. The optical device 500 may emit or receive infrared, ultraviolet, and/or visible light. For example, the optical device 500 may be an optical sensor capable of sensing light incident upon the display device 10, such as a proximity sensor, an ambient light sensor, a camera sensor, and/or an image sensor.

The color filter layer CFL may be disposed on the touch sensing layer TSU. The color filter layer CFL may include a plurality of color filters, which correspond to their respective light-emitting areas. Each of the color filters may selectively transmit light of a particular wavelength and may block or absorb light of other wavelengths. The color filter layer CFL may absorb some of the light entering from outside the display device 10, thus reducing reflected light caused by external light. Therefore, the color filter layer CFL can prevent or reduce color distortion caused by the reflection of external light.

As the color filter layer CFL is disposed directly on the touch sensing layer TSU, the display device 10 may not require a separate substrate for the color filter layer CFL. Therefore, the thickness of the display panel 100 can be relatively thin.

In one or more embodiments, the display panel 100 may be bent in a bending area BA. The bending area BA may be a part of the subarea SBA and may be spaced from the main area MA.

The substrate 110 and the circuit layer 120 may be bent in the bending area BA, which corresponds to a part of the subarea SBA. Accordingly, the size of a bezel area that can be perceived by the user as the non-display area NA can be reduced or minimized.

FIG. 4 is a plan view of a display panel according to one or more embodiments of the present disclosure. FIG. 4 illustrates the display panel 100 in an unfolded, non-bent state.

Referring to FIG. 4, the display panel 100 may include the main area MA and the subarea SBA. The main area MA may include the display area DA and the non-display area NA, and the subarea SBA may include a bank area BNKA, a driving circuit mounting area ICA, and a pad area PA.

The display area DA may be an area where the pixels PX are disposed. The pixels PX and wires (or portions of wires) connected to the pixels PX may be disposed in the display area DA.

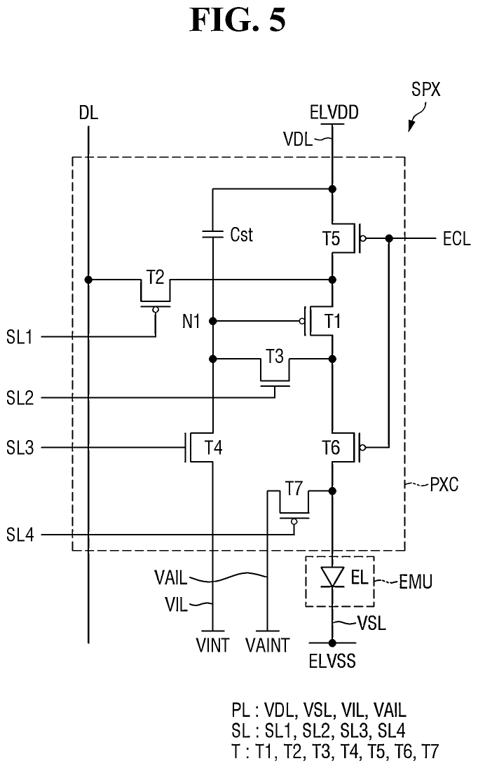

The pixels PX may be provided in the circuit layer 120 and the light-emitting element layer 130 of the display panel 100. For example, the pixels PX may include pixel circuits (“PXC” of FIG. 5), which include circuit elements disposed in the circuit layer 120, and light-emitting elements (“EL” of FIG. 5), which are disposed in the light-emitting element layer 130.

Each of the pixels PX may include at least two subpixels SPX emitting different colors of light. For example, the pixels PX may include first-color subpixels SPX1 emitting first-color light (e.g., red light), second-color subpixels SPX2 emitting second-color light (e.g., green light), and third-color subpixels SPX3 emitting third-color light (e.g., blue light).

At least one first-color subpixel SPX1, at least one second-color subpixel SPX2, and at least one third-color subpixel SPX3 that are adjacent to one another may form one unit pixel PX. For example, one first-color subpixel SPX1, two second-color subpixels SPX2, and one third-color subpixel SPX3 that are adjacent to one another may form one unit pixel PX. Each unit pixel PX may emit various colors of light, including white light, due to the mixing of beams of light emitted from its subpixels (SPX1, SPX2, and SPX3). In one or more embodiments, first-color subpixels SPX1 and third-color subpixels SPX3 may be alternately arranged along the first direction DR1 and/or the second direction DR2, and second-color subpixels SPX2 may be arranged continuously and/or sequentially along the first direction DR1. The type, the shape, and/or the layout of subpixels (SPX1, SPX2, and SPX3) may vary. Additionally, the type, the number, the ratio, and/or the layout of subpixels (SPX1, SPX2, and SPX3) that form each unit pixel PX may also vary.

The encapsulation layer 140 may be disposed on the pixels PX. For example, the encapsulation layer 140 may be provided at least in the display area DA to cover the pixels PX, and a part of the encapsulation layer 140 may extend into the non-display area NA.

Wires may be provided in the circuit layer 120 and may be positioned in both the display area DA and the non-display area NA. Moreover, the wires may also be positioned in the subarea SBA. For example, the wires may extend from the subarea SBA through the non-display area NA to the display area DA.

The non-display area NA may be positioned around the display area DA. For example, the non-display area NA may be the edge area of the main area MA positioned on the periphery of the display area DA.

The non-display area NA may include a dam area DAMA, which is spaced from the display area DA, a first non-display area NA1, which is disposed between the display area DA and the dam area DAMA, and a second non-display area NA2, which is disposed on the periphery of the dam area DAMA. The dam area DAMA may be an area where a dam around (e.g., surrounding) the display area DA is disposed. The second non-display area NA2 may include an inorganic encapsulation area IEA (also referred to as a bonding area) where the inorganic encapsulation layers of the encapsulation layer 140 are bonded together.

The subarea SBA may include the bank area BNKA, the driving circuit mounting area ICA, and the pad area PA, which are sequentially disposed on one side of the main area MA. Wires (or portions of wires), a bank, and pads PD may be disposed in the subarea SBA. At least some of the wires may extend into the main area MA and may be connected to the pixels PX.

The bank area BNKA may be an area where a bank including at least one organic layer is disposed. In one or more embodiments, the bank area BNKA may include the bending area BA. For example, the bank area BNKA may include the bending area BA, which is spaced from the main area MA, and first and second edge areas BEA1 and BEA2, which are positioned on both sides of the bending area BA in the first direction DR1. The bank may be provided in the bending area BA and its surrounding areas (e.g., the first and second edge areas BEA1 and BEA2 of the bank area BNKA) to cover the wires passing through the bending area BA. The display panel 100 may be bent in the bending area BA so that a part of the subarea SBA may be positioned on the rear side of the main area MA.

The driving circuit mounting area ICA may be an area where the driving unit 200 is disposed. Pads for connecting at least some wires to the driving unit 200 may be disposed in the driving circuit mounting area ICA. For example, input pads for connecting the driving unit 200 to particular pads (e.g., data input pads) of the pad area PA and output pads for connecting the driving unit 200 to the pixels PX may be disposed in the driving circuit mounting area ICA.

In one or more embodiments, the driving unit 200 may not be disposed on the display panel 100. In this case, the display panel 100 may not include the driving circuit mounting area ICA, and only wires may be disposed between the bank area BNKA and the pad area PA.

The pad area PA may be an area where the pads PD for connecting the display panel 100 and/or the driving unit 200 to the circuit board 300 are disposed. The circuit board 300 may be disposed in, or bonded onto, the pad area PA.

The pads PD, including power pads and signal pads connected to the pixels PX, the driving unit 200, and/or the embedded circuits, may be disposed in the pad area PA. Power voltages for driving the pixels PX, the driving unit 200, and/or the embedded circuits may be supplied to the power pads. Driving signals for driving the pixels PX, the driving unit 200, and/or the embedded circuits and/or image data may be provided to the signal pads (e.g., pads PD). The types, the locations, the layout, and/or the number of pads PD may vary.

FIG. 5 is a circuit diagram of a subpixel according to one or more embodiments of the present disclosure.

Referring to FIG. 5, a pixel circuit (also referred to as a pixel driving unit) PXC of a pixel PX of the display device 10 may include first through seventh transistors T1 through T7. The scan lines SL, which are connected to the pixel PX, may include first, second, third, and fourth scan lines SL1, SL2, SL3, and SL4, and the power lines PL connected to the pixel PX may include a first pixel power line VDL, a second pixel power line VSL, a first initialization power line VIL, and a second initialization power line VAIL. Furthermore, the pixel circuit PXC may also be connected to an emission control line ECL.

A sub-pixel SPX may include a light-emitting unit EMU, which includes at least one light-emitting element EL, and the pixel circuit PXC, which is connected to the light-emitting unit EMU.

The light-emitting element EL may be connected between the second pixel power line VSL, to which a second pixel power voltage ELVSS is applied, and the pixel circuit PXC. In one or more embodiments, the second pixel power voltage ELVSS may be a low-voltage pixel driving voltage. The light-emitting element EL, which is a light source for the pixel PX, may receive a driving current supplied from the pixel circuit PXC and may emit light.

The light-emitting element EL may be an organic light-emitting diode (OLED), but the disclosure is not limited thereto. Alternatively, the light-emitting element EL may be an inorganic light-emitting element, a quantum-dot light-emitting element, or another type of light-emitting element.

The pixel circuit PXC may control the driving current supplied to the light-emitting element EL and may thereby control the emission timing and the luminance of the light-emitting element EL. The pixel circuit PXC may include one or more pixel transistors T and a capacitor Cst. In one or more embodiments, the pixel circuit PXC may include a plurality of pixel transistors T, and the pixel transistors T may include the first through seventh transistors T1 through T7.

The first transistor T1 may include a gate electrode connected to a first node N1, a first electrode electrically connected to the first pixel power line VDL through the fifth transistor T5, and a second electrode electrically connected to the light-emitting unit EMU through the sixth transistor T6. One of the first and second electrodes of the first transistor T1 may be a source electrode, and the other electrode may be a drain electrode. The first transistor T1 may control a source-drain current (hereinafter referred to as a driving current) flowing between the first and second electrodes of the first transistor T1 based on the voltage applied to the gate electrode of the first transistor T1, for example, the voltage of the first node N1 that corresponds to the voltage of a data signal data. For example, the first transistor T1 may be the driving transistor of the sub-pixel SPX.

The second transistor T2 may include a gate electrode connected to the first scan line SL1, a first electrode connected to the data line DL, and a second electrode connected to the first electrode of the first transistor T1. The second transistor T2 may be turned on by a first scan signal supplied from the first scan line SL1, electrically connecting the first electrode of the first transistor T1 and the data line DL. When the second transistor T2 is turned on, the voltage of the data signal supplied from the data line DL may be applied to the first electrode of the first transistor T1.

The third transistor T3 may include a gate electrode connected to the second scan line SL2, a first electrode connected to the second electrode of the first transistor T1, and a second electrode connected to the gate electrode (e.g., to the first node N1) of the first transistor T1. The third transistor T3 may be turned on by a second scan signal supplied from the second scan line SL2, electrically connecting the gate electrode and the second electrode of the first transistor T1. When the third transistor T3 is turned on, the first transistor T1 may operate as a diode (e.g., the first transistor T1 may be diode-connected).

The fourth transistor T4 may include a gate electrode connected to the third scan line SL3, a first electrode connected to the gate electrode of the first transistor T1 (e.g., to the first node N1), and a second electrode connected to the first initialization power line VIL. The fourth transistor T4 may be turned on by a third scan signal supplied from the third scan line SL3, electrically connecting the gate electrode of the first transistor T1 and the first initialization power line VIL. When the fourth transistor T4 is turned on, the first initialization voltage VINT (e.g., a gate initialization voltage) of the first initialization power line VIL may be applied to the gate electrode of the first transistor T1.

The fifth transistor T5 may include a gate electrode connected to the emission control line ECL, a first electrode connected to the first pixel power line VDL, and a second electrode connected to the first electrode of the first transistor T1. The fifth transistor T5 may be turned on by an emission control signal supplied from the emission control line ECL, electrically connecting the first electrode of the first transistor T1 and the first pixel power line VDL, to which the first pixel power voltage ELVDD is applied. When the fifth transistor T5 is turned on, the first pixel power voltage ELVDD may be applied to the first electrode of the first transistor T1. In one or more embodiments, the second first pixel power voltage ELVDD may be a high-level pixel driving voltage.

The sixth transistor T6 may include a gate electrode connected to the emission control line ECL, a first electrode connected to the second electrode of the first transistor T1, and a second electrode connected to the light-emitting element EL. The sixth transistor T6 may be turned on by an emission control signal supplied from the emission control line ECL, electrically connecting the first transistor T1 and the light-emitting element EL. When the fifth and sixth transistors T5 and T6 are both turned on, a driving current corresponding to the voltage of the gate electrode of the first transistor T1 may flow to the light-emitting element EL.

The seventh transistor T7 may include a gate electrode connected to the fourth scan line SL4, a first electrode connected to the anode electrode of the light-emitting element EL, and a second electrode connected to the second initialization power line VAIL. The seventh transistor T7 may be turned on by a fourth scan signal supplied from the fourth scan line SL4, electrically connecting the anode electrode of the light-emitting element EL and the second initialization power line VAIL. The fourth scan signal may be the same as or different from the first scan signal. When the seventh transistor T7 is turned on, a second initialization voltage VAINT from the second initialization power line VAIL (e.g., an anode electrode initialization voltage) may be applied to the anode electrode e of the light-emitting element EL.

The capacitor Cst may be connected between the gate electrode of the first transistor T1 (e.g., to the first node N1) and the first pixel power line VDL. The capacitor Cst may be charged to a voltage corresponding to the data signal voltage applied to the gate electrode of the first transistor T1 (e.g., to the first node N1).

The active layers (e.g., semiconductor patterns including channel regions) of the pixel transistors T (e.g., the first through seventh transistors T1 through T7) may include one of the following semiconductor materials: polysilicon, amorphous silicon, and an oxide semiconductor. In one or more embodiments, some of the pixel transistors T may be formed as transistors of one conductivity type, and other pixel transistors T may be formed as transistors of a different conductivity type. Moreover, some of the pixel transistors T may include different types of semiconductor materials.

For example, the first, second, fifth, sixth, and seventh transistors T1, T2, T5, T6, and T7 may be formed as P-type transistors (e.g., P-type metal-oxide semiconductor field-effect transistors (MOSFETs)) with active layers formed of polysilicon, while the third and fourth transistors T3 and T4 may be formed as N-type transistors (e.g., N-type MOSFETs) with active layers formed of an oxide semiconductor. In one embodiment, transistors with active layers formed of polysilicon and transistors with active layers formed of an oxide semiconductor may be disposed in different layers within the circuit layer 120.

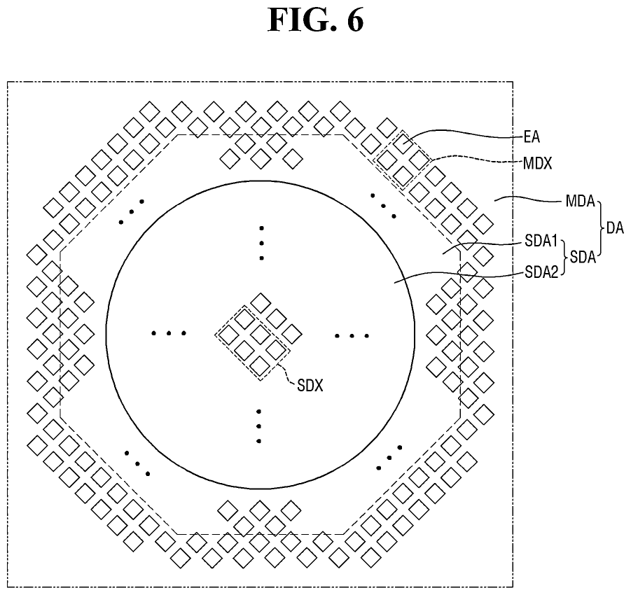

FIG. 6 is a plan view illustrating the arrangement of pixels in the main display area and the sub-display area of the display device of FIG. 1. FIG. 6 illustrates the array of pixels (MDX and SDX) in the sub-display area SDA and the main display area MDA within the display area DA of the display device 10.

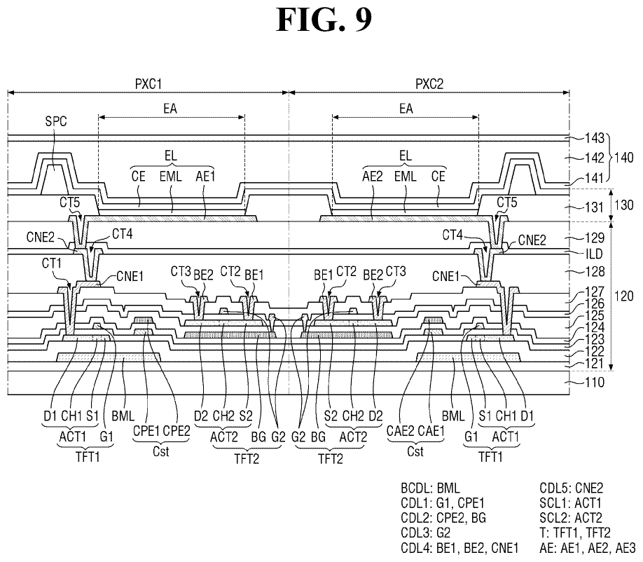

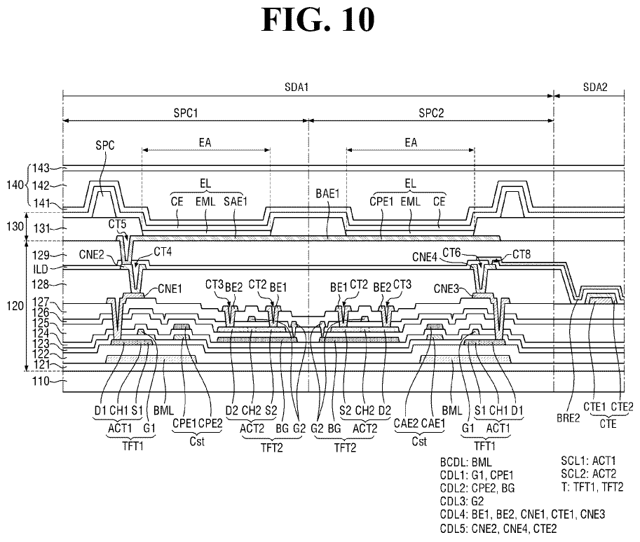

Referring to FIG. 6, the display area DA of the display device 10 may include the main display area MDA and the sub-display area SDA. As previously mentioned, the sub-display area SDA may be an area where components are disposed below the substrate SUB of the display device 10. A plurality of main display pixels MDX may be arranged in the main display area MDA, and a plurality of sub-display pixels SDX may be arranged in the sub-display area SDA. Each of the main display pixels MDX and sub-display pixels SDX may include one or more light-emitting areas EA, and one or more light-emitting elements (“EL” of FIGS. 9 and 10) may be disposed in each of the light-emitting areas EA to emit light.

In the main display area MDA, a plurality of light-emitting elements EL, which emit light, and pixel circuits PXC, which are electrically connected to the light-emitting elements EL and apply signals for the emission of light by the light-emitting elements EL, may be disposed. The main display area MDA may be an area where the light-emitting elements EL and the pixel circuits PXC are arranged in a predetermined pattern. Each of the light-emitting elements EL may form a light-emitting area EA, and multiple light-emitting areas EA may form a single main display pixel MDX together. For example, in the main display area MDA, four light-emitting areas EA may form a single main display pixel MDX together, and each of the light-emitting areas EA may correspond to a pixel circuit PXC of a subpixel SPX. As illustrated in FIG. 4, one main display pixel MDX may include four subpixels (SPX1, SPX2, and SPX3) and four light-emitting areas EA, which correspond to the four subpixels (SPX1, SPX2, and SPX3). Four light-emitting areas EA may form a single main display pixel MDX together to express white gradation.

Light-emitting elements EL, which emit light, may also be disposed in the sub-display area SDA to form light-emitting areas EA, and multiple light-emitting areas EA may form a single sub-display pixel SDX together. However, unlike the main display area MDA, the sub-display area SDA, which is an area that overlaps with components (e.g., the optical device 500) disposed on the rear side of the substrate 110 of the display panel 100, may have a structure considering the transmission rate of light. Specifically, the sub-display area SDA of the display area DA may include a first sub-display area SDA1 where light-emitting areas EA and pixel circuits PXC are disposed and a second sub-display area SDA2 where light-emitting areas EA are formed but pixel circuits PXC are not disposed.

The first sub-display area SDA1 may be disposed around the second sub-display area SDA2. In one or more embodiments, the second sub-display area SDA2 may be disposed in the middle of the sub-display area SDA, and the first sub-display area SDA1 may surround the second sub-display area SDA2. However, the present disclosure is not limited to this. Alternatively, the first sub-display area SDA1 may be disposed on at least one side of the second sub-display area SDA2.

Pixel circuits PXC for the emission of light by light-emitting elements EL disposed in the sub-display area SDA may be provided in the first sub-display area SDA1. On the contrary, no pixel circuits PXC may be disposed in the second sub-display area SDA2.

Pixel circuits PXC electrically connected to the light-emitting elements EL disposed in the sub-display area SDA may be disposed in the first sub-display area SDA1. Some of the pixel circuits PXC disposed in the first sub-display area SDA1 may be electrically connected to the light-emitting elements EL disposed in the first sub-display area SDA1, while other pixel circuits PXC may be connected to the light-emitting elements EL disposed in the second sub-display area SDA2. The second sub-display area SDA2, which overlaps with the optical device 500 of the display panel 100, may have a high light transmittance rate due to the absence of pixel circuits PXC therein. The second sub-display area SDA2 may emit light due to the presence of light-emitting areas EA therein and may have a high light transmittance rate that allows the optical device 500, which is disposed on the rear side of the display panel 100, to receive light.

In the sub-display area SDA, unlike in the main display area MDA, light-emitting elements EL and pixel circuits PXC may not necessarily correspond one-to-one to one another. For example, in the main display area MDA, a single pixel circuit PXC may be electrically connected to a single light-emitting element EL. In the main display area MDA, each pixel circuit PXC may correspond to a single light-emitting element EL or a light-emitting component formed in one opening of a pixel-defining layer (“131” of FIG. 9) that will be described later. Conversely, the pixel circuits PXC disposed in the first sub-display area SDA1 may be electrically connected to the light-emitting elements EL disposed in the first and second sub-display areas SDA1 and SDA2. Accordingly, each pixel circuit PXC disposed in the first sub-display area SDA1 may correspond to multiple light-emitting elements EL (or multiple light-emitting components) formed in multiple openings of the pixel-defining layer 131 (see FIG. 9).

Each sub-display pixel SDX formed by multiple light-emitting areas EA in the sub-display area SDA may have a different layout from the main display pixels MDX. For example, each of the main display pixels MDX may include four light-emitting areas EA, and each of the sub-display pixels SDX may include six light-emitting areas EA. The four light-emitting areas EA of each of the main display pixels MDX correspond to their corresponding pixel circuits PXC, and each of the main display pixels MDX may include four pixel circuits PXC. Conversely, the six light-emitting areas EA of each of the sub-display pixels SDX may be paired up to form three pairs corresponding to their respective pixel circuits PXC. That is, each of the sub-display pixels SDX may include six light-emitting areas EA that are enabled by three pixel circuits PXC to emit light. Accordingly, the sub-display area SDA may exhibit a different luminance and resolution from the main display area MDA.

The arrangement and the configuration of the pixels (MDX and SDX) in the main display area MDA and the sub-display area SDA of the display device 10 will hereinafter be described.

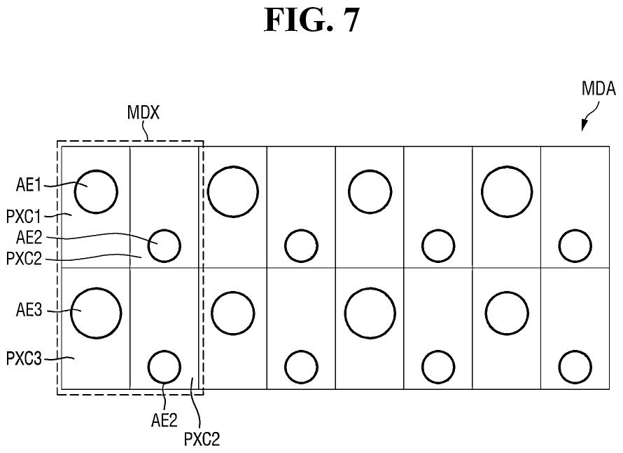

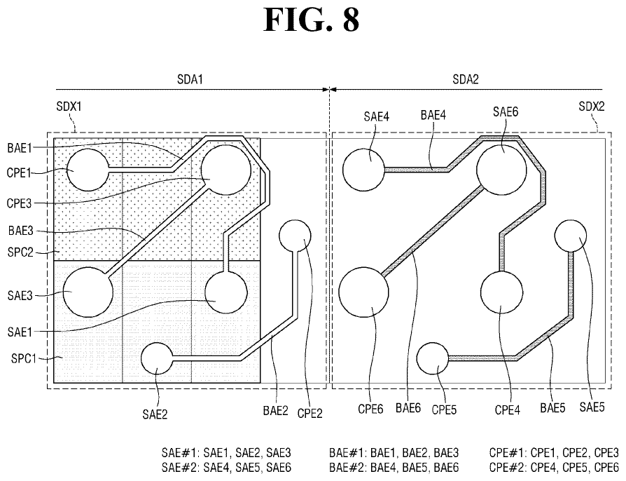

FIG. 7 is a plan view illustrating the arrangement of the pixel electrodes included in the main pixels disposed in the main display area of FIG. 6. FIG. 8 is a plan view illustrating the arrangement of the pixel electrodes included in the subpixels disposed in the sub-display area of FIG. 6.

FIG. 7 illustrates the arrangement of pixel electrodes (AE1, AE2, and AE3) and pixel circuits (PXC1, PXC2, and PXC3) of four main display pixels MDX. FIG. 8 illustrates the arrangement of subpixel electrodes (e.g., subpixel electrodes SAE1, SAE2, and SAE3 of the sub-display pixel SDX1, and subpixel electrodes SAE4, SAE5, and SAE6 of the sub-display pixel SDX2) and subpixel circuits (SPC1 and SPC2) of a sub-display pixel SDX1 in the first sub-display area SDA1 and of a sub-display pixel SDX2 in the second sub-display area SDA2.

Referring to FIG. 7, the display device 10 may include a plurality of pixel electrodes (AE1, AE2, and AE3), which are disposed in the main display area MDA. The pixel electrodes (AE1, AE2, and AE3) may be the anode electrodes of light-emitting elements EL emitting different colors of light. For example, first pixel electrodes AE1 may be the anode electrodes of light-emitting elements EL emitting the first-color light and may be disposed in first light-emitting areas, second pixel electrodes AE2 may be the anode electrodes of light-emitting elements EL emitting the second-color light and may be disposed in second light-emitting areas, and third pixel electrodes AE3 may be the anode electrodes of light-emitting elements EL emitting the third-color light and may be disposed in third light-emitting areas. In one or more embodiments, the first light-emitting areas may emit red light, the second light-emitting areas may emit green light, and the third light-emitting areas may emit blue light. However, the disclosure is not limited to this. A plurality of light-emitting areas EA may be defined by the openings formed in the pixel-defining layer 131 of the light-emitting layer 130.

The pixel electrodes (AE1, AE2, and AE3) may be arranged in, for example, a PENTILE® fashion, such as a diamond PENTILE® fashion. PENTILE® is a registered trademark of Samsung Display Co., Ltd., Republic of Korea. For example, the first pixel electrodes AE1 and the third pixel electrodes AE3 may be alternately arranged and spaced from one another in the first and second directions DR1 and DR2. The second pixel electrodes AE2 may be spaced from one another in the first and second directions DR1 and DR2 and may be spaced from the first pixel electrodes AE1 and the third pixel electrodes AE3 in diagonal directions.

The first pixel electrodes AE1, the second pixel electrodes AE2, and the third pixel electrodes AE3 may be included in their corresponding subpixels SPX and may belong to their corresponding main display pixels MDX. For example, each main display pixel MDX may include one first subpixel SPX1, two second subpixels SPX2, and one third subpixel SPX3 and may also include one first pixel electrode AE1, two second pixel electrodes AE2, and one third pixel electrode AE3.

The pixel circuits (PXC1, PXC2, and PXC3) disposed in the main display area MDA may correspond one-to-one to the pixel electrodes (AE1, AE2, and AE3). For example, first pixel circuits PXC1 may correspond to and may be electrically connected to their respective first pixel electrodes AE1, second pixel circuits PXC2 may correspond to and be electrically connected to their respective second pixel electrodes AE2, and third pixel circuits PXC3 may correspond to and may be electrically connected to their respective third pixel electrodes AE3. A main display pixel MDX including four pixel electrodes (AE1, AE2, and AE3) may include four pixel circuits (PXC1, PXC2, and PXC3).

Referring to FIG. 8, the display device 10 may include a plurality of subpixel electrodes SAE, copy pixel electrodes CPE, and bridge electrodes BAE, which are disposed in the sub-display area SDA. The subpixel electrodes SAE and the copy pixel electrodes CPE may be the anode electrodes of light-emitting elements EL. That is, in the first and second sub-display areas SDA1 and SDA2, like in the main display area MDA, light-emitting elements EL may be disposed to emit light.

The configuration of the sub-display pixels SDX in the sub-display area SDA of the display device 10 may differ from the configuration of the main display pixels MDX in the main display area MDA. For example, each sub-display pixel SDX may have subpixel electrodes SAE and copy pixel electrodes CPE that are electrically connected to one another through bridge electrodes BAE. The subpixel electrodes SAE and the copy pixel electrodes CPE that are connected through the bridge electrodes BAE may be the anode electrodes of light-emitting elements EL emitting the same color of light.

For example, a first subpixel electrode SAE1 and a first copy pixel electrode CPE1, which are disposed in the first sub-display area SDA1, may be electrically connected to each other via a first bridge electrode BAE1 and may form light-emitting elements EL emitting the first-color light. The light-emitting areas EA where the first subpixel electrode SAE1 and the first copy pixel electrode CPE1 are disposed may emit the same color of light.

Similarly, a second subpixel electrode SAE2 and a second copy pixel electrode CPE2, which are disposed in the first sub-display area SDA1, may be electrically connected to each other through a second bridge electrode BAE2, a third subpixel electrode SAE3 and a third copy pixel electrode CPE3, which are disposed in the first sub-display area SDA1, may be electrically connected through a third bridge electrode BAE3. The second subpixel electrode SAE2 and the second copy pixel electrode CPE2 may form light-emitting elements EL emitting the second-color light, and the third subpixel electrode SAE3 and the third copy pixel electrode CPE3 may form light-emitting elements EL emitting the third-color light. The light-emitting areas EA where the second subpixel electrode SAE2 and the second copy pixel electrode CPE2 are disposed may emit the same color of light, and the light-emitting areas EA with the third subpixel electrode SAE3 and the third copy pixel electrode CPE3 are disposed may emit the same color of light.

A fourth subpixel electrode SAE4 and a fourth copy pixel electrode CPE4, which are disposed in the second sub-display area SDA2, may be electrically connected to each other through a fourth bridge electrode BAE4. A fifth subpixel electrode SAE5 and a fifth copy pixel electrode CPE5, which are disposed in the first sub-display area SDA1, may be electrically connected to each other through a fifth bridge electrode BAE5, and a sixth subpixel electrode SAE6 and a sixth copy pixel electrode CPE6, which are disposed in the first sub-display area SDA1, may be electrically connected to each other through a sixth bridge electrode BAE6.

The fourth subpixel electrode SAE4 and the fourth copy pixel electrode CPE4 form light-emitting elements EL emitting the first-color light, the fifth subpixel electrode SAE5 and the fifth copy pixel electrode CPE5 may form light-emitting elements EL emitting the second-color light, and the sixth subpixel electrode SAE6 and the sixth copy pixel electrode CPE6 may form light-emitting elements EL emitting the third-color light.

Similarly to pixel electrodes AE of the main display area MDA, the subpixel electrodes SAE and the copy pixel electrodes CPE may be arranged in, for example, a PENTILE® pattern, such as a diamond PENTILE® pattern. For example, the first and third subpixel electrodes SAE1 and SAE3 may be spaced from each other in the second direction DR2, and the third and first copy pixel electrodes CPE3 and CPE1 may be spaced from the first and third subpixel electrodes SAE1 and SAE3, respectively, in the first direction DR1. The fourth and sixth subpixel electrodes SAE4 and SAE6 may be spaced from each other in the second direction DR2 and the sixth and fourth copy pixel electrodes CPE6 and CPE4 may be spaced from the fourth and sixth subpixel electrodes SAE4 and SAE6, respectively, in the first direction DR1. The second subpixel electrode SAE2 and the second copy pixel electrode CPE2 may be diagonally spaced from each other with the first subpixel electrode SAE1 interposed therebetween. The fifth subpixel electrode SAE5 and the fifth copy pixel electrode CPE5 may be diagonally spaced from each other with the fourth copy pixel electrode CPE4 interposed therebetween. The bridge electrodes BAE may be disposed to connect their respective pairs of subpixel electrodes SAE and copy pixel electrodes CPE without passing through one another and other subpixel electrodes SAE and copy pixel electrodes CPE.

The first sub-display pixel SDX1, which is disposed in the first sub-display area SDA1, may include six light-emitting areas EA or six pixel electrodes, including the first, second, and third subpixel electrodes SAE1, SAE2, and SAE3 and the first, second, and third copy pixel electrodes CPE1, CPE2, and CPE3. The second sub-display pixel SDX2, which is disposed in the second sub-display area SDA2, may include six light-emitting areas EA or six pixel electrodes, including the fourth, fifth, and sixth subpixel electrodes SAE4, SAE5, and SAE6 and the fourth, fifth, and sixth copy pixel electrodes CPE4, CPE5, and CPE6. Each of the sub-display pixels SDX in the sub-display area SDA, unlike each of the main display pixels MDX in the main display area MDA, may have a relatively larger number of light-emitting areas EA emitting the same color of light. However, the number or density of light-emitting areas EA per unit area may be greater in the main display pixels MDX than in the sub-display pixels SDX. Moreover, the numbers of light-emitting elements EL emitting the first-color light and the third-color light may be greater in the sub-display pixels SDX than in the main display pixels MDX, but the number of light-emitting elements emitting the second-color light may be the same in both the sub-display pixels SDX and the main display pixels MDX. Accordingly, the display device 10 may have a higher resolution in the main display area MDA than in the sub-display area SDA. The sub-display area SDA may have a lower resolution than the main display area MDA in consideration of the light transmittance to the optical device 500, which is disposed below the sub-display area SDA.

In one or more embodiments, first subpixel circuits SPC1, which are electrically connected to the first sub-display pixel SDX1, and second subpixel circuits SPC2, which are electrically connected to the second sub-display pixel SDX2, may be disposed in the first sub-display area SDA1. On the other hand, in the second sub-display area SDA2, no pixel circuits may be disposed, but the subpixel electrodes SAE, the copy pixel electrodes CPE, and the bridge electrodes BAE as well as bridge patterns electrically connecting the subpixel electrodes SAE, the copy pixel electrodes CPE, and the bridge electrodes BAE to the second subpixel circuits SPC2 may be disposed.

As will be described later, the subpixel electrodes SAE, the copy pixel electrodes CPE, and the bridge electrodes BAE may be disposed in the sub-display area SDA of the display device 10, and may be distinguished from one another based on their positions and connection structures. For example, the first, second, and third subpixel electrodes SAE1, SAE2, and SAE3, which are disposed in the first sub-display area SDA1, may be connected to the first, second, and third copy pixel electrodes CPE1, CPE2, and CPE3 through the first, second, and third bridge electrodes BAE1, BAE2, and BAE3, which are positioned in (e.g., at) the same layer. The subpixel electrodes SAE, copy pixel electrodes CPE, and bridge electrodes BAE disposed in the first sub-display area SDA1 may be referred to as first-type subpixel electrodes SAE #1, first-type copy pixel electrodes CPE #1, and first-type bridge electrodes BAE #1, respectively.

Conversely, the fourth, fifth, and sixth subpixel electrodes SAE4, SAE5, and SAE6, which are disposed in the second sub-display area SDA2, may be connected to the fourth, fifth, and sixth copy pixel electrodes CPE4, CPE5, and CPE6 through the fourth, fifth, and sixth bridge electrodes BAE4, BAE5, and BAE6, which are positioned in different layers. The subpixel electrodes SAE, copy pixel electrodes CPE, and bridge electrodes BAE disposed in the second sub-display area SDA2 may be referred to as second-type subpixel electrodes SAE #2, second-type copy pixel electrodes CPE #2, and second-type bridge electrodes BAE #2, respectively.

The first subpixel circuits SPC1 may be electrically connected to the subpixel electrodes SAE disposed in the first sub-display pixel SDX1, i.e., the first-type subpixel electrodes SAE #1. Each of the first subpixel circuits SPC1 may be electrically connected to one of the first, second, and third subpixel electrodes SAE1, SAE2, and SAE3. The first-type copy pixel electrodes CPE #1, which are disposed in the first sub-display pixel SDX1, may be electrically connected to the first-type subpixel electrodes SAE #1 through the first-type bridge electrodes BAE #1, and multiple light-emitting elements EL including a pair of subpixel and copy pixel electrodes SAE and CPE that are electrically connected may emit light at the same time (e.g., may emit light concurrently). The subpixel electrodes SAE disposed in the first sub-display pixel SDX1 may overlap with their corresponding first subpixel circuits SPC1.

The second subpixel circuits SPC2 may be electrically connected to the subpixel electrodes SAE disposed in the second sub-display pixel SDX2, i.e., the second-type subpixel electrodes SAE #2. The second subpixel circuits SPC2 may be electrically connected to the fourth, fifth, and sixth subpixel electrodes SAE4, SAE5, and SAE6. The second-type copy pixel electrodes CPE #2, which are disposed in the second sub-display pixel SDX2, may be electrically connected to the second-type subpixel electrodes SAE #2 through the second-type bridge electrodes BAE #2, and multiple light-emitting elements EL including a pair of subpixel and copy pixel electrodes SAE and CPE that are electrically connected may emit light at the same time (may emit light concurrently). Connection patterns connecting the second subpixel circuits SPC2 and the subpixel electrodes SAE of the second sub-display pixel SDX2 may be disposed in the sub-display area SDA. At least some of the copy pixel electrodes CPE disposed in the first sub-display pixel SDX1 may be disposed to overlap with the second subpixel circuits SPC2. Other copy pixel electrodes CPE disposed in the first sub-display pixel SDX1 may be disposed in an area where none of the subpixel circuits (SPC1 and SPC2) are disposed.

In one or more embodiments, the first-type subpixel electrodes SAE #1, the first-type copy pixel electrodes CPE #1, and the first-type bridge electrodes BAE #1, which are disposed in the first sub-display area SDA1, may be arranged in (e.g., at) the same layer, forming integrated patterns. For example, the first, second, and third bridge electrodes BAE1, BAE2, and BAE3, which are the bridge electrodes BAE disposed in the first sub-display area SDA1, may be bridge parts integrated with the first, second, and third subpixel electrodes SAE1, SAE2, and SAE3, respectively, and with the first, second, and third copy pixel electrodes CPE1, CPE2, and CPE3, respectively. On the contrary, the second-type subpixel electrodes SAE #2 and the second-type copy pixel electrodes CPE #2, disposed in the second sub-display area SDA2, may be arranged in (e.g., at) the same layer, but the second-type bridge electrodes BAE #2, also disposed in the second sub-display area SDA2, may be arranged in a different layer from the second-type subpixel electrodes SAE #2 and the second-type copy pixel electrodes CPE #2. For example, the fourth, fifth, and sixth bridge electrodes BAE4, BAE5, and BAE6, which are the bridge electrodes BAE disposed in the second sub-display area SDA2, may be connection electrodes that are disposed in a different layer from the fourth, fifth, and sixth subpixel electrodes SAE4, SAE5, and SAE6 and the fourth, fifth, and sixth copy pixel electrodes CPE4, CPE5, and CPE6, and may electrically connect the fourth, fifth, and sixth subpixel electrodes SAE4, SAE5, and SAE6 and the fourth, fifth, and sixth copy pixel electrodes CPE4, CPE5, and CPE6.

The first-type subpixel electrodes SAE #1, which are disposed in the first sub-display area SDA1, may be arranged to overlap with the first subpixel circuits SPC1 and may be integrated with the first-type copy pixel electrodes CPE #1 through the first-type bridge electrodes BAE #1, which are disposed in the same layer as the first-type subpixel electrodes SAE #1. The second-type subpixel electrodes SAE #2, which are disposed in the second sub-display area SDA2, may be electrically connected to the second subpixel circuits SPC2, but may be arranged not to overlap with the second subpixel circuits SPC2. The second-type subpixel electrodes SAE #2, which are disposed in the second sub-display area SDA2, may be electrically connected to the second-type copy pixel electrodes CPE #2 through the second-type bridge electrodes BAE #2, which are disposed in a different layer from the second-type subpixel electrodes SAE #2, and may be electrically connected to the second subpixel circuits SPC2 through bridge patterns disposed therebelow. This will be described later with reference to other drawings.

The subpixel circuits (SPC1 and SPC2) may be disposed only in the first sub-display area SDA1 in consideration of the transmittance of light. As the number of subpixel circuits (SPC1 and SPC2) per unit area is smaller in the first sub-display area SDA1 than in the main display area MDA, the subpixel electrodes SAE and the copy pixel electrodes CPE may be paired up in the sub-display pixels (SDX1 and SDX2) disposed in the sub-display area SDA, thereby forming a plurality of light-emitting areas EA.

FIG. 9 is a cross-sectional view illustrating a main display area of the display device of FIG. 1.

FIG. 9 is a schematic cross-sectional view illustrating two light-emitting elements EL and first and second pixel circuits PXC1 and PXC2 in the main display area MDA. Specifically, FIG. 9 depicts a cross-section that crosses parts of the first and second pixel circuits PXC1 and PXC2, which are adjacent to each other.

Referring to FIG. 9, the display panel 100 may include the substrate 110, the circuit layer 120, which is disposed on the substrate 110, the light-emitting element layer 130, and the encapsulation layer 140. The circuit layer 120, the light-emitting element layer 130, and the encapsulation layer 140 may be sequentially disposed or stacked in the thickness direction on the substrate 110 (e.g., the third direction DR3).

The substrate 110 may be formed of a flexible material that is bendable, foldable, and/or rollable. The substrate 110 may be formed of an insulating material such as a polymer resin. For example, the substrate 110 may be formed of polyimide.

The circuit layer 120 may include pixel circuits PXC and wires. For example, the circuit layer 120 may include circuit elements (e.g., pixel transistors T and capacitors Cst) that form the pixel circuits PXC of each main display pixel MDX and wires (e.g., the power lines PL, the scan lines SL, the emission control lines ECL, and the data lines DL) that are electrically connected to the pixel circuits PXC.

FIG. 9 illustrates first thin-film transistors (TFTs) TFT1 (also referred to as first pixel transistors), second TFTs TFT2 (also referred to as second pixel transistors), and the capacitors Cst, which are included in the pixel circuits PXC of each main display pixel MDX, among other elements provided in the circuit layer 120. The first TFTs TFT1 may be representative first-type transistors (e.g., P-type transistors) including a first semiconductor material (e.g., polysilicon), from among other pixel transistors T. For example, the first TFTs TFT1 may correspond to one of the first, second, fifth, sixth, and/or seventh transistors T1, T2, T5, T6, and/or T7 of FIG. 5. FIG. 9 depicts first-type transistors (e.g., the sixth transistor T6 of FIG. 5) connected to one or more connection electrodes (e.g., a first connection electrode CNE1 and/or a second connection electrode CNE2) as the first TFTs TFT1. The second TFTs TFT2 may be representative second-type transistors (e.g., N-type transistors) including a second semiconductor material (e.g., an oxide semiconductor) among other pixel transistors T. For example, the second TFTs TFT2 may correspond to one of the third and fourth transistors T3 and T4.

The circuit layer 120 may include semiconductor layers, which are for forming circuit elements and wires, conductive layers, and insulating films, which are disposed between and/or around the conductive layers and the semiconductor layers. For example, the circuit layer 120 may include a barrier layer 121, a lower conductive layer BCDL, a buffer layer 122, a first semiconductor layer SCL1 (e.g., a polysilicon semiconductor layer), a first insulating layer 123 (e.g., a first gate insulating film), a first conductive layer CDL1 (e.g., a first gate conductive layer), a second insulating layer 124 (e.g., a second gate insulating film), a second conductive layer CDL2 (e.g., a second gate conductive layer), a third insulating layer 125 (e.g., a first interlayer insulating film), a second semiconductor layer SCL2 (e.g., an oxide semiconductor layer), a fourth insulating layer 126 (e.g., a third gate insulating film), a third conductive layer CDL3 (e.g., a third gate conductive layer), a fifth insulating layer 127 (e.g., a second interlayer insulating film), and a fourth conductive layer CDL4 (e.g., a first source-drain conductive layer), and a sixth insulating layer 128 (e.g., a first via layer or a first planarization film), which are sequentially disposed on the substrate 110 in the third direction DR3. In one or more embodiments, the circuit layer 120 may further include an interlayer insulating layer ILD, a fifth conductive layer CDL5 (e.g., a second source-drain conductive layer), and a seventh insulating layer 129 (e.g., a second via layer or a second planarization film), which are sequentially disposed on the sixth insulating layer 128.

The barrier layer 121 may be disposed on the substrate 110. The barrier layer 121 may protect the elements disposed in the circuit layer 120 and the light-emitting element layer 130 from moisture infiltrating through the substrate 110, which is permeable. The barrier layer 121 may include at least one inorganic film containing an inorganic insulating material (e.g., silicon nitride, silicon oxide, silicon oxynitride, titanium oxide, aluminum oxide, and/or another inorganic insulating material). The material of the barrier layer 121 may vary.

The lower conductive layer BCDL may be disposed on the barrier layer 121. The lower conductive layer BCDL may include a lower metal layer BML, which overlaps with the active layer of at least one of the pixel transistors T, for example, first active layers ACT1 and/or second active layers ACT2, and/or at least one wire (or part of the at least one wire). The lower metal layer BML is illustrated in FIG. 9 as being disposed to overlap with the first active layers ACT1 of the first TFTs TFT1 and first capacitor electrodes CAE1 and second capacitor electrodes CAE2 of the capacitors Cst, but the present disclosure is not limited thereto. For example, the lower metal layer BML may be patterned into a suitable size and/or shape and may be disposed on the entire pixel circuits PXC or on parts of the pixel circuits PXC. For example, the lower metal layer BML may be disposed only on a part of a pixel area overlapping with the first transistor T1 of FIG. 5. In one or more embodiments, the lower metal layer BML may be used as a light-shielding pattern and/or the back-gate electrodes of the pixel transistors T.

The buffer layer 122 may be disposed on the lower conductive layer BCDL and may cover the lower conductive layer BCDL. The buffer layer 122 may include at least one inorganic film with an inorganic insulating material.

The first TFTs TFT1, the second TFTs TFT2, and the capacitors Cst may be disposed on one surface of the substrate 110 with the buffer layer 122. The first TFTs TFT1 may include the first active layers ACT1 and first gate electrodes G1. The second TFTs TFT2 may include the second active layers ACT2 and second gate electrodes G2. In one or more embodiments, the second TFTs TFT2 may include back-gate electrodes BG. The capacitors Cst may include the first capacitor electrodes CAE1 and the second capacitor electrodes CAE2.

The first semiconductor layer SCL1 may be disposed on the buffer layer 122. The first semiconductor layer SCL1 may include the first active layers ACT1 of the first TFTs TFT1. For example, the first semiconductor layer SCL1 may include the first active layers ACT1 of the first, second, fifth, sixth, and/or seventh transistors T1, T2, T5, T6, and/or T7.

The first active layers ACT1 are provided on the buffer layer 122 and may include the first semiconductor material (e.g., polysilicon). The first active layers ACT1 may include first channel regions CH1, first source regions S1, and first drain regions D1. The first channel regions CH1 may overlap with the first gate electrodes G1 in the third direction DR3. The first source regions S1 may be disposed on sides of the first channel regions CH1, and the first drain regions D1 may be disposed on other sides of the first channel regions CH1. The first source regions S1 and the first drain regions D1 may be regions formed by doping ions or impurities into a semiconductor to impart conductivity for forming the first active layers ACT1. In one or more embodiments, the first source regions S1 may be the source electrodes of the first TFTs TFT1. In one or more embodiments, the first TFTs TFT1 may include separate source electrodes connected to the first source regions S1. In one or more embodiments, the first drain regions D1 may be the drain electrodes of the first TFTs TFT1. In one or more embodiments, the first TFTs TFT1 may include separate drain electrodes connected to the first drain regions D1.

The first insulating layer 123 may be disposed on the first semiconductor layer SCL1 and the buffer layer 122. The first insulating layer 123 may cover the first semiconductor layer SCL1 and the buffer layer 122.

The first conductive layer CDL1 may be disposed on the first insulating layer 123. The first conductive layer CDL1 may include the first gate electrodes G1 of the first TFTs TFT1. The first gate electrodes G1 may be disposed to overlap with portions (e.g., the first channel regions CH1) of the first active layers ACT1. In one or more embodiments, the first conductive layer CDL1 may further include wires (or portions of wires), conductive patterns (e.g., bridge patterns), and/or capacitor electrodes. For example, the first conductive layer CDL1 may further include the first capacitor electrodes CAE1 of the capacitors Cst.

In one or more embodiments, the first capacitor electrodes CAE1 may be integrally formed with the gate electrodes of at least the first TFTs TFT1. For example, the first capacitor electrode CAE1 of each of the capacitors Cst may be integrally formed with the gate electrode of the first transistor T1 of FIGS. 5 and 6. For example, the first capacitor electrode CAE1 of each of the capacitors Cst and the gate electrode of the first transistor T1 may be formed as a single conductive pattern, and the second capacitor electrode CAE2 of the corresponding capacitor Cst may be disposed to overlap with the conductive pattern.

The second insulating layer 124 may be disposed on the first conductive layer CDL1 and the first insulating layer 123. The second insulating layer 124 may cover the first conductive layer CDL1 and the first insulating layer 123.

The second conductive layer CDL2 may be disposed on the second insulating layer 124. The second conductive layer CDL2 may include electrodes of the capacitors Cst, for example, the second capacitor electrodes CAE2. In one or more embodiments, the second conductive layer CDL2 may further include electrodes, wires (or portions of wires), and/or conductive patterns (e.g., bridge patterns). For example, the second conductive layer CDL2 may further include the back-gate electrodes BG, which are connected to the second gate electrodes G2 of the second TFTs TFT2.

The third insulating layer 125 may be disposed on the second conductive layer CDL2 and the second insulating layer 124. The third insulating layer 125 may cover the second conductive layer CDL2 and the second insulating layer 124.

The second semiconductor layer SCL2 may be disposed on the third insulating layer 125. The second semiconductor layer SCL2 may include the second active layers ACT2 of the second TFTs TFT2. For example, the second semiconductor layer SCL2 may include the second active layers ACT2 of the third and fourth transistors T3 and T4.

The second active layers ACT2 may be provided in the second semiconductor layer SCL2 and may include the second semiconductor material (e.g., an oxide semiconductor). For example, the second active layers ACT2 may include indium-gallium-zinc-oxygen (IGZO), indium-gallium-zinc-tin-oxygen (IGZTO), and/or indium-gallium-tin-oxide (IGTO).

The second active layers ACT2 may include the second channel regions CH2, the second source regions S2, and the second drain regions D2. The second channel regions CH2 may overlap with the second gate electrodes G2 in the third direction DR3. The second source regions S2 may be disposed on sides of the second channel regions CH2, and the second drain regions D2 may be disposed on other sides of the second channel regions CH2. The second source regions S2 and the second drain regions D2 may be areas with conductivity, where ions or impurities are doped in the semiconductor for forming the second active layers ACT2. In one or more embodiments, the second source regions S2 may be the source electrodes of the second TFTs TFT2. In one or more embodiments, the second TFTs TFT2 may include separate source electrodes connected to the second source regions S2. In one or more embodiments, the second drain regions D2 may be the drain electrodes of the second TFTs TFT2. In one or more embodiments, the second TFTs TFT2 may include separate drain electrodes connected to the second drain regions D2.

The fourth insulating layer 126 may be disposed on the second semiconductor layer SCL2 and the third insulating layer 125. The fourth insulating layer 126 may cover the second semiconductor layer SCL2 and the third insulating layer 125.

In one or more embodiments, the first, second, third, and fourth insulating layers 123, 124, 125, and 126 may be inorganic insulating films with an inorganic insulating material (e.g., silicon nitride, silicon oxide, silicon oxynitride, titanium oxide, aluminum oxide, and/or another inorganic insulating material) and may have a single-layer or multi-layer structure. At least two of the first, second, third, and fourth insulating layers 123, 124, 125, and 126 may contain the same material or different materials. The materials of the first, second, third, and fourth insulating layers 123, 124, 125, and 126 may vary.

The third conductive layer CDL3 may be disposed on the fourth insulating layer 126. The third conductive layer CDL3 may include the second gate electrodes G2 of the second TFTs TFT2. The second gate electrodes G2 may be disposed to overlap with portions of the second active layers ACT2, for example, the second channel regions CH2. In one or more embodiments, the third conductive layer CDL3 may further include wires (or portions of wires), conductive patterns (e.g., bridge patterns), and/or capacitor electrodes.

In one or more embodiments, the electrodes, conductive patterns, and/or wires provided in each of the bottom conductive layer BCDL, the first conductive layer CDL1, the second conductive layer CDL2, and the third conductive layer CDL3 may include a conductive material such as least one of, for example, molybdenum (Mo), aluminum (AI), chromium (Cr), gold (Au), titanium (Ti), nickel (Ni), neodymium (Nd), copper (Cu), or another metal, an alloy thereof, or another conductive material and may have a single-layer or multi-layer structure. For example, the electrodes, conductive patterns, and/or wires provided in each of the bottom conductive layer BCDL, the first conductive layer CDL1, the second conductive layer CDL2, and the third conductive layer CDL3 may include Mo or another metal material. At least two of the conductive layers from among the bottom conductive layer BCDL, the first conductive layer CDL1, the second conductive layer CDL2, and the third conductive layer CDL3 may include the same material or different materials. The materials of the bottom conductive layer BCDL, the first conductive layer CDL1, the second conductive layer CDL2, and the third conductive layer CDL3 are not limited and may vary.

The fifth insulating layer 127 may be disposed on the third conductive layer CDL3 and the fourth insulating layer 126. The fifth insulating layer 127 may cover the third conductive layer CDL3 and the fourth insulating layer 126.

The fourth conductive layer CDL4 may be disposed on the fifth insulating layer 127. The fourth conductive layer CDL4 may include the first connection electrodes CNE1 (or the drain electrodes of the first TFTs TFT1), first conductive patterns BE1 (or the source electrodes of the second TFTs TFT2), and second conductive patterns BE2 (or the drain electrodes of the second TFTs TFT2). The first connection electrodes CNE1, which are provided in the fourth conductive layer CDL4, may be connected to the first drain regions D1 of the first active layers ACT1 through first contact holes CT1, which penetrate the first, second, third, fourth, and fifth insulating layers 123, 124, 125, 126, and 127. The first conductive patterns BE1, which are provided in the fourth conductive layer CDL4, may be connected to the second source regions S2 of the second active layers ACT2 through second contact holes CT2, which penetrate the fourth and fifth insulating layers 126 and 127. The second conductive patterns BE2 may be connected to the second drain regions D2 of the second active layers ACT2 through third contact holes CT3, which penetrate the fourth and fifth insulating layers 126 and 127. In one or more embodiments, the fourth conductive layer CDL4 may further include wires (or portions of wires) and/or conductive patterns (e.g., bridge patterns). For example, the fourth conductive layer CDL4 may include some of the power lines PL, which are provided within or outside the display area DA (e.g., the first pixel power line VDL and/or the second pixel power line VSL).

The sixth insulating layer 128 may be on the fourth conductive layer CDL4 and the fifth insulating layer 127. The sixth insulating layer 128 may cover the fourth conductive layer CDL4 and the fifth insulating layer 127.

The fifth conductive layer CDL5 may be disposed on the sixth insulating layer 128. The fifth conductive layer CDL5 may include the second connection electrodes CNE2. The second connection electrodes CNE2, which are provided in the fifth conductive layer CDL5, may be connected to the first connection electrodes CNE1 through fourth contact holes CT4 (or first via holes), which penetrate the sixth insulating layer 128. In one or more embodiments, the fifth conductive layer CDL5 may further include wires (or portions of wires) and/or conductive patterns (e.g., bridge patterns). For example, the fifth conductive layer CDL5 may include some of the power lines PL (e.g., the first pixel power line VDL and/or the second pixel power line VSL), which are provided within and/or outside the display area DA.

In one or more embodiments, the electrodes, conductive patterns, and/or wires provided in each of the fourth and fifth conductive layers CDL4 and CDL5 may include a conductive material (e.g., Mo, Al, Cr, Au, Ti, Ni, Nd, Cu or another metal, an alloy thereof, or another conductive material) and may have a single-layer or multi-layer structure. For example, the electrodes, conductive patterns, and/or wires provided in each of the fourth and fifth conductive layers CDL4 and CDL5 may be formed with a tri-layer structure of titanium/aluminum/titanium (Ti/Al/Ti). The fourth and fifth conductive layers CDL4 and CDL5 may include the same material or different materials. The materials of the fourth and fifth conductive layers CDL4 and CDL5 may vary.

The interlayer insulating layer ILD may be disposed on the fifth conductive layer CDL5 and the sixth insulating layer 128. The interlayer insulating layer ILD may cover the fifth conductive layer CDL5 and the sixth insulating layer 128. The interlayer insulating layer ILD may cover a plurality of patterns disposed in the sub-display area SDA that will be discussed later. The interlayer insulating layer ILD may include an inorganic insulating material and may cover underlying layers disposed in the sub-display area SDA, instead of the sixth and seventh insulating layers 128 and 129 that are not provided in the sub-display area SDA.

The seventh insulating layer 129 may be disposed on the interlayer insulating layer ILD. The seventh insulating layer 129 may cover the interlayer insulating layer ILD.

In one or more embodiments, the sixth and seventh insulating layers 128 and 129 may be organic insulating films including an organic insulating material (e.g., an acryl resin, an epoxy resin, a phenolic resin, a polyamide resin, a polyimide resin, and/or another organic insulating material) and may have a single-layer or multi-layer structure. The sixth and seventh insulating layers 128 and 129 may include the same material or different materials. The materials of the sixth and seventh insulating layers 128 and 129 may vary.

The light-emitting element layer 130 may include a first pixel-defining film 131, which defines the light-emitting areas EA of the pixels PX, and the light-emitting elements EL, which are positioned in the light-emitting areas EA. In one or more embodiments, the light-emitting element layer 130 may further include spacers SPC, which are disposed on parts of the first pixel-defining film 131.

The light-emitting elements EL may include pixel electrodes (AE1, AE2, and AE3) (e.g., anode electrodes) connected to the transistors T (e.g., the first TFTs TFT1), which are included in the main display pixels MDX, through the first connection electrodes CNE1 and/or the second connection electrodes CNE2 and may also include light-emitting layers EML and a common electrode CE (e.g., a cathode electrode), which are sequentially disposed on the pixel electrodes (AE1, AE2, and AE3). In one or more embodiments, the light-emitting elements EL may further include a first intermediate layer (e.g., a hole layer including a hole transport layer) disposed between the (AE1, AE2, and AE3) and the light-emitting layers EML, and a second intermediate layer (e.g., an electron layer including an electron transport layer) disposed between the light-emitting layers EML and the common electrode CE.

The pixel electrodes (AE1, AE2, and AE3) of the light-emitting element EL may include a conductive material and may be disposed on the circuit layer 120. For example, the pixel electrodes (AE1, AE2, and AE3) may be disposed on the seventh insulating layer 129 to correspond to their respective light-emitting areas EA. The pixel electrodes AE may be connected to the second connection electrodes CNE2 through fifth contact holes CT5 (or second via holes), which penetrate the seventh insulating layer 129 and the interlayer insulating layer ILD.

In one or more embodiments, the pixel electrodes (AE1, AE2, and AE3) may include a metal material with high reflectivity. For example, the pixel electrodes (AE1, AE2, and AE3) may have a single-layer structure of Mo, Ti, Cu, and/or Al, and/or a multi-layer structure of indium-tin-oxide (ITO), zinc oxide (ZnO), indium oxide (In₂O₃), and silver (Ag), magnesium (Mg), aluminum (AI), platinum (Pt), lead (Pb), Au, and/or Ni (e.g., ITO/Mg, ITO/MgF, ITO/Ag, and/or ITO/Ag/ITO).

The light-emitting layers EML of the light-emitting elements EL may include a high molecular weight material or a low molecular weight material. In one or more embodiments, the light-emitting layers EML may be arranged in each of the pixel electrodes (AE1, AE2, and AE3) of each main display pixel MDX, and may emit light of colors corresponding to the light-emitting areas EA. In one or more embodiments, the light-emitting layers EML may be a common layer shared by different color light-emitting areas EA, and wavelength conversion layers and/or color filters corresponding to the colors (or wavelength bands) of light intended to be emitted by at least some of the subpixels SPX of each main display pixel MDX may be disposed in the light-emitting areas EA of the corresponding subpixels SPX.

The common electrode CE of the light-emitting elements EL may include a conductive material and may be connected to the second pixel power line VSL. In one or more embodiments, the common electrode CE may be a common layer formed over the entire display area DA, covering the light-emitting layers EML and the first pixel-defining film 131. The common electrode CE may be disposed across the entire main display area MDA and the sub-display area SDA. In one or more embodiments, the common electrode CE may be formed of a transparent conductive oxide (TCO) capable of transmitting light therethrough, such as ITO or IZO, or a semi-transmissive metal material like Mg, Ag, or an alloy of Mg and Ag. If the common electrode CE is formed of a semi-transmissive metal material, an improvement in light emission efficiency due to the micro cavity effect can be expected.

The first pixel-defining film 131 may have openings corresponding to the light-emitting areas EA and may be around (e.g., may surround) the light-emitting areas EA. For example, the first pixel-defining film 131 may be formed to cover the edges of the pixel electrodes (AE1, AE2, and AE3) of the light-emitting elements EL and may include openings that exposes the rest of the pixel electrodes (AE1, AE2, and AE3). The areas (or their surroundings) where the exposed pixel electrodes (AE1, AE2, and AE3) and the light-emitting layers EML overlap may be defined as the light-emitting areas EA of each main display pixel MDX.

In one or more embodiments, the first pixel-defining film 131 may include at least one organic film containing an organic insulating material. For example, the first pixel-defining film 131 may contain an acrylic resin, an epoxy resin, a phenolic resin, a polyamide resin, a polyimide resin, an unsaturated polyester resin, a polyphenylene resin, a polyphenylene sulfide resin, benzocyclobutene (BCB), and/or another organic insulating material.

The spacers SPC may be positioned on a portion of the first pixel-defining film 131. The spacers SPC may include at least one organic film containing an organic insulating material. The spacers SPC may include the same material as, or a different material from, the first pixel-defining film 131. In one or more embodiments, the first pixel-defining film 131 and the spacers SPC may be sequentially formed by separate mask processes. In one or more embodiments, the first pixel-defining film 131 and the spacers SPC may be formed concurrently (e.g., simultaneously) using a halftone mask, in which case, the first pixel-defining film 131 and the spacers SPC can be viewed as a single integrated insulating film. The organic insulating material forming the spacers SPC is not particularly limited and may vary.

The encapsulation layer 140 may be disposed on the light-emitting element layer 130 in the main area MA. For example, the encapsulation layer 140 may be disposed in the display area DA and the non-display area NA to cover the light-emitting element layer 130. The encapsulation layer 140 may prevent the infiltration of oxygen or moisture to the light-emitting element layer 130 and may alleviate the electrical or physical impact to the circuit layer 120 and the light-emitting element layer 130.

In one or more embodiments, the encapsulation layer 140 may include a first inorganic encapsulation film 141, an organic encapsulation film 142, and a second inorganic encapsulation film 143, which are sequentially disposed on the light-emitting element layer 130. The first and second inorganic encapsulation films 141 and 143 may contain an inorganic material, and the organic encapsulation film 142 may contain organic material.

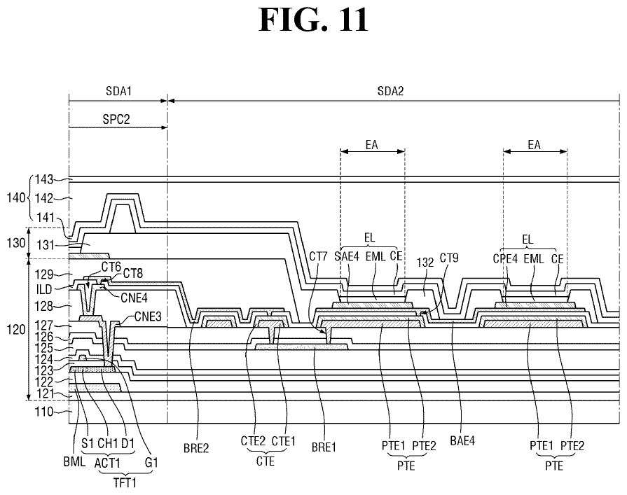

FIGS. 10 and 11 are cross-sectional views illustrating sub-display areas of the display device of FIG. 1. FIGS. 10 and 11 illustrate the cross-sections of light-emitting elements EL disposed in the first and second sub-display areas SDA1 and SDA2, and the electrical connection structure between first and second subpixel circuits SPC1 and SPC2 and light-emitting elements EL. Specifically, FIG. 10 illustrates the cross-sectional structure of the area where a first subpixel electrode SAE1 and a first copy pixel electrode CPE1 are disposed, and FIG. 11 illustrates the structure of the area where a fourth subpixel electrode SAE4 and a fourth copy pixel electrode CPE4 are disposed.

Referring to FIGS. 10 and 11, the display device 10 may include the first subpixel circuits SPC1 and SPC2, which are disposed in the first sub-display area SDA1. The first subpixel circuits SPC1 and SPC2 may include devices or elements formed by the wires and patterns in the first, second, third, fourth, and fifth conductive layers CDL1, CDL2, CDL3, CDL4, and CDL5 and the first and second semiconductor layers SCL1 and SCL2, which are disposed on the substrate 110. The first and second subpixel circuits SPC1 and SPC2 may have the same configuration and connection structure as the first and second pixel circuits PXC1 and PXC2 described with reference to FIG. 9, and thus, detailed descriptions of the configuration and connection structure of the first and second subpixel circuits SPC1 and SPC2 will be omitted.

The first subpixel circuit SPC1, which is disposed in the first sub-display area SDA1, may be electrically connected to a first subpixel electrode SAE1. A first connection electrode CNE1 of the first subpixel circuit SPC1 is connected to a second connection electrode CNE2 of the first subpixel circuit SPC1, which is disposed on the sixth insulating layer 128, and the second connection electrode CNE2 may be connected to the first subpixel electrode SAE1, which is disposed on the seventh insulating layer 129. The first subpixel electrode SAE1 is disposed to overlap with, and connected to, the first subpixel circuit SPC1, serving as the anode electrode of a light-emitting element EL. The first subpixel electrode SAE1 may overlap with an opening of the first pixel-defining film 131 and may form the light-emitting element EL together with a light-emitting layer EML disposed in the opening of the first pixel-defining film 131, and a common electrode CE disposed on the light-emitting layer EML.

The first copy pixel electrode CPE1, which is disposed in the first sub-display area SDA1, may be electrically connected to the first subpixel electrode SAE1. In one or more embodiments, the first copy pixel electrode CPE1 may be integrated with the first subpixel electrode SAE1 through a first bridge electrode BAE1, which is disposed in (e.g., at) the same layer as the first copy pixel electrode CPE1. The first copy pixel electrode CPE1 and the first bridge electrode BAE1 may be disposed directly on the seventh insulating layer 129. The first copy pixel electrode CPE1 may be disposed to overlap with the second subpixel circuit SPC2, but may be electrically connected to the first subpixel circuit SPC1 through the first subpixel electrode SAE1. The first copy pixel electrode CPE1 may overlap with the opening of the first pixel-defining film 131 and may form the light-emitting element EL together with the light-emitting layer EML, which is disposed in the opening of the first pixel-defining film 131, and the common electrode CE, which is disposed on the light-emitting layer EML. Electrical signals for the emission of light by the light-emitting elements EL may be applied concurrently (e.g., simultaneously) to both the first subpixel electrode SAE1 and the first copy pixel electrode CPE1, and multiple light-emitting elements EL including the first subpixel electrode SAE1 or the first copy pixel electrode CPE1 may emit light at the same time (e.g., may emit light concurrently). The light-emitting layer EML disposed on the first subpixel electrode SAE1 and the light-emitting layer EML disposed on the first copy pixel electrodes CPE1 may both emit the same color of light.

The second subpixel circuit SPC2, which is disposed in the first sub-display area SDA1, may be electrically connected to a fourth subpixel electrode SAE4, a fifth subpixel electrode SAE5, or a sixth subpixel electrode SAE6, which is disposed in the second sub-display area SDA2. No pixel circuits PXC may be disposed in the second sub-display area SDA2, and a plurality of patterns and electrodes that can transmit electrical signals from the second subpixel circuit SPC2 may be included in the second sub-display area SDA2.

The display device 10 may include a plurality of bridge patterns (BRE1 and BRE2), contact patterns CTE (CTE1 and CTE2), and planarization patterns PTE (PTE1 and PTE2), which are disposed in the sub-display area SDA. The bridge patterns (BRE1 and BRE2), the contact patterns CTE, and the planarization patterns PTE may be disposed in one of the first and second semiconductor layers SCL1 and SCL2 and first, second, third, fourth, and fifth conductive layers CDL1, CDL2, CDL3, CDL4, and CDL5 that form pixel circuits PXC or the first and second subpixel circuits SPC1 and SPC2. The bridge patterns (BRE1 and BRE2), the contact patterns CTE, and the planarization patterns PTE may transmit emission signals applied from the second subpixel circuit SPC2 to the fourth subpixel electrode SAE4, disposed in the second sub-display area SDA2.

For example, the bridge patterns (BRE1 and BRE2) may include first bridge patterns BRE1, which are disposed on the third insulating layer 125, and second bridge patterns BRE2, which are disposed on the interlayer insulating layer ILD. The first bridge patterns BRE1 may be disposed in (e.g., at) the same layer as the second semiconductor layer SCL2, but positioned in the second sub-display area SDA2, while the second bridge patterns BRE2 may be disposed across the first and second sub-display areas SDA1 and SDA2. The second bridge patterns BRE2 may be electrically connected to the first bridge patterns BRE1 through the contact patterns CTE, and the first bridge patterns BRE1 may be electrically connected to the subpixel electrodes SAE through the planarization patterns PTE and the bridge electrodes BAE. An emission signal applied from the second subpixel circuit SPC2 may be transmitted to the second bridge patterns BRE2 through third and fourth connection electrodes CNE3 and CNE4, and may also be transmitted to the fourth subpixel electrode SAE4, disposed in the second sub-display area SDA2, through the contact patterns CTE, the first bridge patterns BRE1, the planarization patterns PTE and the fourth bridge electrode BAE4. For example, in the second subpixel circuit SPC2, the fourth conductive layer CDL4 may further include the third connection electrodes CNE3 disposed in the first sub-display area SDA1. The third connection electrodes CNE3 may be connected to the first drain regions D1 of the first active layers ACT1 through contact holes, which penetrate the first, second, third, fourth, and fifth insulating layers 123, 124, 125, 126, and 127. In the second subpixel circuit SPC2, the fifth conductive layer CDL5 may further include the fourth connection electrodes CNE4 disposed in the first sub-display area SDA1. The fourth connection electrodes CNE4, which are provided in the fifth conductive layer CDL5, may be connected to the third connection electrodes CNE3 through sixth contact holes CT6, which penetrate the sixth insulating layer 128.

The contact patterns CTE may be disposed on the fifth insulating layer 127 and may include the first contact patterns CTE1, which are included in the fourth conductive layer CDL4, and the second contact patterns CTE2, which are disposed on the first contact patterns CTE1 and are included in the fifth conductive layer CDL5. The first contact patterns CTE1 and the second contact patterns CTE2 may be arranged to overlap with one another and may be formed as substantially the same patterns. For example, the second contact patterns CTE2 may be formed to cover the outer surfaces (e.g., outer peripheral surfaces) of the first contact patterns CTE1.

A plurality of contact patterns CTE may be positioned near the boundary between the first and second sub-display areas SDA1 and SDA2. As will be described later, some of the contact patterns CTE may be disposed in the first sub-display area SDA1, while other contact patterns CTE may be disposed in the second sub-display area SDA2. The contact patterns CTE may serve as electrodes connecting the first bridge patterns BRE1 and the second bridge patterns BRE2. The first bridge patterns BRE1 may extend from the contact patterns CTE to the fourth subpixel electrode SAE4, disposed in the second sub-display area SDA2. The second bridge patterns BRE2 may extend from the contact patterns CTE to the fourth connection electrode CNE4 of the second subpixel circuit SPC2, disposed in the first sub-display area SDA1. The numbers and arrangement of the bridge patterns (BRE1 and BRE2) and the contact patterns CTE in the sub-display area SDA may be designed to correspond to the numbers and arrangement of the second subpixel circuit SPC2 and the fourth subpixel electrode SAE4 in the second sub-display area SDA2.

The planarization patterns PTE may be disposed on the fifth insulating layer 127 and may include first planarization patterns PTE1, which are included in the fourth conductive layer CDL4, and second planarization patterns PTE2, which are disposed on the first planarization patterns PTE1 and are included in the fifth conductive layer CDL5. The first planarization patterns PTE1 and the second planarization patterns PTE2 may both be disposed in (e.g., at) the same layer as the first contact patterns CTE1 and the second contact patterns CTE2, respectively. Additionally, the cross-sectional arrangement of the first planarization patterns PTE1 and the second planarization patterns PTE2 may be similar to the cross-sectional arrangement of the first contact patterns CTE1 and the second contact patterns CTE2. For example, the first planarization patterns PTE1 and the second planarization patterns PTE2 may be arranged to overlap with one another and may be formed as substantially the same patterns. The second planarization patterns PTE2 may be formed to cover the outer surfaces (e.g., outer peripheral surfaces) of the first planarization patterns PTE1.

A plurality of planarization patterns PTE may be disposed in the second subpixel area SDA2 to overlap with the subpixel electrodes SAE or the copy pixel electrodes CPE. The first planarization patterns PTE1 and the second planarization patterns PTE2 may be paired up to overlap with one another and may also overlap with the subpixel electrodes SAE or the copy pixel electrodes CPE. The first planarization patterns PTE1 and the second planarization patterns PTE2 may form areas in the second sub-display area SDA2 where the subpixel electrodes SAE or the copy pixel electrodes CPE can be formed to be flat.

The sixth and seventh insulating layers 128 and 129, which contain an organic insulating material, may not be disposed in the entire second sub-display area SDA2 to enhance the light transmittance of the second sub-display area SDA2. The sixth and seventh insulating layers 128 and 129 may be disposed in the entire main display area MDA and the entire first sub-display area SDA1, but not entirely in the second sub-display area SDA2. The sixth and seventh insulating layers 128 and 129 may be disposed only near the boundary between the first and second sub-display areas SDA1 and SDA2. The sixth and seventh insulating layers 128 and 129 may not be disposed at least in portions of the second sub-display area SDA2 where the light-emitting elements EL are disposed, or where the subpixel electrodes SAE and the copy pixel electrodes CPE are disposed. The second sub-display area SDA2 may have a higher light transmittance because of the near absence of the sixth and seventh insulating layers 128 and 129, which include an organic insulating material and are thus thick, and as a result, the amount of light incident on the components disposed in the second sub-display area SDA2 or the optical device 500 may increase.

The display device 10 may include a plurality of planarization patterns PTE disposed in the second sub-display area SDA2, and the subpixel electrodes SAE and the copy pixel electrodes CPE may be disposed on the planarization patterns PTE. For example, in the light-emitting elements EL disposed in the second sub-display area SDA2, the subpixel electrodes SAE and the copy pixel electrodes CPE, which serve as the anode electrodes, may be disposed on the planarization patterns PTE. In the second sub-display area SDA2, no planarization layer formed of an organic insulating material may be disposed, but due to the presence of the planarization patterns PTE, the flatness of the anode electrodes of the light-emitting elements EL can be ensured.

Planarization pattern PTE that overlap with the subpixel electrodes SAE disposed in the second sub-display area SDA2 may be connected to the corresponding subpixel electrodes SAE and the first bridge patterns BRE1. The planarization patterns PTE may ensure flatness while also serving as connection electrodes that transmit emission signals applied through the bridge patterns (BRE1 and BRE2) to the subpixel electrodes SAE. In contrast, planarization patterns PTE that overlap with the copy pixel electrodes CPE disposed in the second sub-display area SDA2 may not be connected to the first bridge patterns BRE1. The planarization patterns PTE that overlap with the copy pixel electrodes CPE may also not be connected to the copy pixel electrodes CPE, but the present disclosure is not limited thereto. In one or more embodiments, the planarization patterns PTE that overlap with the copy pixel electrodes CPE may be connected to the copy pixel electrodes CPE.

The interlayer insulating layer ILD may be disposed across the main display area MDA and the sub-display area SDA. In the main display area MDA and the first sub-display area SDA1, the interlayer insulating layer ILD may be disposed on the sixth insulating layer 128 and the fifth conductive layer CDL5, covering the sixth insulating layer 128 and the fifth conductive layer CDL5. Conversely, in the second sub-display area SDA2, the interlayer insulating layer ILD may be disposed on the contact patterns CTE, the planarization patterns PTE, and the fifth insulating layer 127, covering the contact patterns CTE, the planarization patterns PTE, and the fifth insulating layer 127. In the main display area MDA and the first sub-display area SDA1, the seventh insulating layer 129, containing an organic insulating material, may be disposed below the anode electrodes of the light-emitting elements EL, functioning as a via layer, but in the second sub-display area SDA2, the interlayer insulating layer ILD, which includes an inorganic insulating material, may be disposed below the anode electrodes of the light-emitting elements EL, also functioning as a via layer.

Bridge electrodes BAE disposed in the second sub-display area SDA2, specifically the fourth, fifth, and sixth bridge electrodes BAE4, BAE5, and BAE6, may be disposed on the interlayer insulating layer ILD in the second sub-display area SDA2. The fourth, fifth, and sixth bridge electrodes BAE4, BAE5, and BAE6 may include the same material as the second bridge patterns BRE2 and may be disposed in (e.g., at) substantially the same layer as the second bridge patterns BRE2. Similarly to how the second bridge patterns BRE2 are positioned on the interlayer insulating layer ILD in the first sub-display area SDA1, the fourth, fifth, and sixth bridge electrodes BAE4, BAE5, and BAE6 may be positioned on the interlayer insulating layer ILD on the planarization patterns PTE, in the second sub-display area SDA2.

The fourth, fifth, and sixth bridge electrodes BAE4, BAE5, and BAE6 may include first portions that overlap with the planarization patterns PTE and second portions that are connected to different first portions. While first, second, and third bridge electrodes BAE1, BAE2, and BAE3 have an integrated structure with their corresponding subpixel electrodes SAE and copy pixel electrodes CPE, the fourth, fifth, and sixth bridge electrodes BAE4, BAE5, and BAE6 may be disposed in a different layer from their corresponding subpixel electrodes SAE and copy pixel electrodes CPE and may include overlapping portions with their corresponding subpixel electrodes SAE and copy pixel electrodes CPE. For example, the first, second, and third bridge electrodes BAE1, BAE2, and BAE3 may be integrated with the first, second, and third subpixel electrodes SAE1, SAE2, and SAE3, respectively, and the first, second, and third copy pixel electrodes CPE1, CPE2, CPE3, respectively, in the first sub-display area SDA1. In the second sub-display area SDA2, the fourth, fifth, and sixth bridge electrodes BAE4, BAE5, and BAE6 may include first portions that overlap with the fourth, fifth, and sixth subpixel electrodes SAE4, SAE5, and SAE6 and with the fourth, fifth, and sixth copy pixel electrodes CPE4, CPE5, and CPE6 and second portions that are connected to the first portions. The bridge electrodes BAE disposed in the first and second sub-display areas SDA1 and SDA2 may electrically connect the subpixel electrodes SAE and the copy pixel electrodes CPE, but may be disposed in different layers and have different structures.

The portions of the fourth, fifth, and sixth bridge electrodes BAE4, BAE5, and BAE6 that overlap with the fourth, fifth, and sixth subpixel electrodes SAE4, SAE5, and SAE6 may be connected to the planarization patterns PTE disposed therebelow. For example, the first portion of the fourth bridge electrode BAE4 that overlaps with the fourth subpixel electrode SAE4 may be connected to the planarization patterns PTE through a ninth contact hole CT9, which penetrates the interlayer insulating layer ILD. The planarization patterns PTE that overlap with, and are connected to, the fourth subpixel electrode SAE4 may be electrically connected to the second subpixel circuit SPC2 through the first bridge patterns BRE1. On the other hand, the fourth bridge electrode BAE4 may not be connected to the planarization patterns PTE that overlap with the fourth copy pixel electrode CPE4. The planarization patterns PTE that overlap with the fourth copy pixel electrode CPE4 and are not connected to the first bridge patterns BRE1 may not receive emission signals from the second subpixel circuit SPC2. Accordingly, even if the fourth bridge electrode BAE4 is not connected to the planarization patterns PTE that overlap with the copy pixel electrodes CPE, the fourth bridge electrode BAE4 still can receive emission signals through other portions connected to the first bridge patterns BRE1, but the present disclosure is not limited thereto. Alternatively, the fourth, fifth, and sixth bridge electrodes BAE4, BAE5, and BAE6, disposed in the second sub-display area SDA2, may be connected to the planarization patterns PTE disposed therebelow.

The fourth, fifth, and sixth subpixel electrodes SAE4, SAE5, and SAE6 may be disposed on the fourth, fifth, and sixth bridge electrodes BAE4, BAE5, and BAE6, respectively, and the fourth, fifth, and sixth copy pixel electrodes CPE4, CPE5, and CPE6 may also be disposed on the fourth, fifth, and sixth bridge electrodes BAE4, BAE5, and BAE6, respectively. The fourth, fifth, and sixth subpixel electrodes SAE4, SAE5, and SAE6 and the fourth, fifth, and sixth copy pixel electrodes CPE4, CPE5, and CPE6 may be disposed to overlap with the planarization patterns PTE and may have flat surfaces irrespective of the steps formed by the layers disposed therebelow. The fourth, fifth, and sixth subpixel electrodes SAE4, SAE5, and SAE6 and the fourth, fifth, and sixth copy pixel electrodes CPE4, CPE5, and CPE6 may serve the same role as the subpixel electrodes SAE and the copy pixel electrodes CPE, respectively, disposed in the first sub-display area SDA1.

For example, the fourth, fifth, and sixth subpixel electrodes SAE4, SAE5, and SAE6 and the fourth, fifth, and sixth copy pixel electrodes CPE4, CPE5, and CPE6 may serve as the anode electrodes of the light-emitting elements EL disposed in the second sub-display area SDA2 and may be electrically connected to one another through the fourth, fifth, and sixth bridge electrodes BAE4, BAE5, and BAE6. Light-emitting elements EL that include one of the fourth, fifth, and sixth subpixel electrodes SAE4, SAE5, and SAE6 or one of the fourth, fifth, and sixth copy pixel electrodes CPE4, CPE5, and CPE6, which are electrically connected to the fourth, fifth, and sixth subpixel electrodes SAE4, SAE5, and SAE6, may emit light at the same time (e.g., may emit light concurrently).

The second pixel-defining film 132 may be disposed in the second sub-display area SDA2. The second pixel-defining film 132 may be formed of the same material as the first pixel-defining layer 131 and may be disposed in substantially the same layer as the first pixel-defining layer 131. However, the second pixel-defining film 132 may be disposed in a reduced or minimal area in consideration of the light transmittance of the second sub-display area SDA2. For example, the second pixel-defining film 132 may be disposed to cover the edges of the fourth, fifth, and sixth subpixel electrodes SAE4, SAE5, and SAE6 and the edges of the fourth, fifth, and sixth copy pixel electrodes CPE4, CPE5, and CPE6 in the second sub-display area SDA2. In one or more embodiments, the second pixel-defining film 132 may overlap with ninth contact holes CT9, which penetrate the interlayer insulating layer ILD, at the edges of the fourth, fifth, and sixth subpixel electrodes SAE4, SAE5, and SAE6. Parts of the fourth, fifth, and sixth subpixel electrodes SAE4, SAE5, and SAE6 that are not covered by the second pixel-defining film 132 may have flat surfaces, and the light-emitting layers EML disposed on the flat surfaces may form flat surfaces regardless of the steps caused by ninth contact holes CT9.

The common electrode CE may be disposed across the main display area MDA and the sub-display area SDA. In the second sub-display area SDA2, the common electrode CE may be disposed over the second pixel-defining film 132 and light-emitting layers EML.

The second subpixel circuit SPC2, disposed in the first sub-display area SDA1, may be electrically connected to the fourth subpixel electrode SAE4. The third connection electrode CNE3 of the second subpixel circuit SPC2 is connected to the fourth connection electrode CNE4, disposed on the sixth insulating layer 128, through a sixth contact hole CT6, and the fourth connection electrode CNE4 may be connected to the second bridge patterns BRE2, disposed on the interlayer insulating layer ILD, via an eighth contact hole CT8. The second bridge patterns BRE2 may be electrically connected to the subpixel electrodes SAE disposed in the second sub-display area SDA2, for example, the fourth, fifth, and sixth subpixel electrode SAE4, SAE5, and SAE6, through the contact patterns CTE, the first bridge patterns BRE1, and the planarization patterns PTE. FIG. 11 illustrates a structure where the second subpixel circuit SPC2 is electrically connected to the fourth subpixel electrode SAE4. The fourth, fifth, and sixth subpixel electrode SAE4, SAE5, and SAE6, disposed in the second sub-display area SDA2, may not overlap with, but may be electrically connected to, their corresponding second subpixel circuits SPC2 through the bridge patterns (BRE1 and BRE2) and may serve as the anode electrodes of the light-emitting elements EL disposed in the second sub-display area SDA2.

The fourth copy pixel electrode CPE4, disposed in the second sub-display area SDA2, may be electrically connected to the fourth subpixel electrode SAE4. As previously described, the fourth copy pixel electrode CPE4 may be electrically connected to the fourth subpixel electrode SAE4 through the fourth bridge electrode BAE4 disposed therebelow. The fourth bridge electrode BAE4 is disposed on the interlayer insulating layer ILD, and the fourth subpixel electrode SAE4 and the fourth copy pixel electrode CPE4 may be disposed directly on the fourth bridge electrode BAE4. The fourth copy pixel electrode CPE4 may be disposed not to overlap with the second subpixel circuit SPC2, but may be electrically connected to the second subpixel circuit SPC2 through the fourth subpixel electrode SAE4.

The fourth copy pixel electrode CPE4 may overlap with an opening of the second pixel-defining film 132, and may form a light-emitting element EL together with a light-emitting layer EML disposed in the opening of the second pixel-defining film 132 and the common electrode CE on the light-emitting layer EML. Electrical signals for the emission of light by the light-emitting element EL may be concurrently (e.g., simultaneously) applied to both the fourth subpixel electrode SAE4 and the fourth copy pixel electrode CPE4, and multiple light-emitting elements EL including the fourth subpixel electrode SAE4 or the fourth copy pixel electrode CPE4 may emit light at the same time. The light-emitting layer EML disposed on the fourth subpixel electrode SAE4 and the light-emitting layer EML disposed on the fourth copy pixel electrode CPE4 may emit light of the same color.

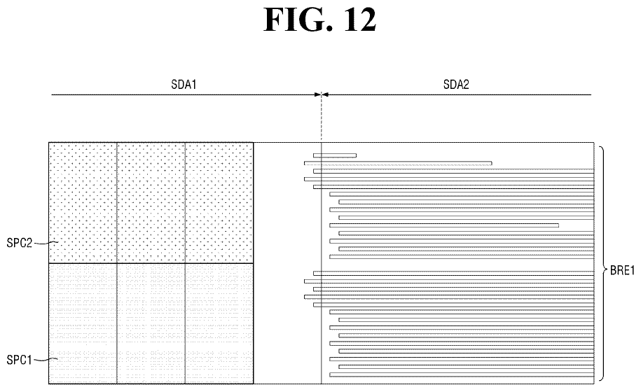

FIGS. 12 through 19 are plan views illustrating a plurality of layers disposed in the sub-display area of the display device of FIG. 1. FIGS. 12 through 19 illustrate the planar layout of layers disposed in the sub-display area SDA, particularly, the second semiconductor layer SCL2 and several layers disposed on the second semiconductor layer SCL2. A description of the planar structure of the layers disposed in the sub-display area SDA will hereinafter be presented.

Referring to FIG. 12, in the first sub-display area SDA1, the first subpixel circuits SPC1 and the second subpixel circuits SPC2 may be disposed, and in the second sub-display area SDA2, a plurality of first bridge patterns BRE1 may be disposed on the second semiconductor layer SCL2.

The first subpixel circuits SPC1 may be pixel circuits that are electrically connected to the subpixel electrodes SAE disposed in the first sub-display area SDA1, and the second subpixel circuits SPC2 may be pixel circuits that are electrically connected to the subpixel electrodes SAE disposed in the second sub-display area SDA2. The structures of the first subpixel circuits SPC1 and second subpixel circuits SPC2 have already been described above with reference to FIGS. 10 and 11, and thus, detailed descriptions thereof will be omitted.

The first bridge patterns BRE1 may be spaced from one another and may have an elongated shape in one direction. The first bridge patterns BRE1 may extend from the vicinity of the boundary between the first and second sub-display areas SDA1 and SDA2 to the second sub-display area SDA2. For example, first ends of the first bridge patterns BRE1 may overlap with and may be connected to the first contact patterns CTE1, while second ends of the first bridge patterns BRE1 may extend to the subpixel electrodes SAE disposed in the second sub-display area SDA2. FIG. 12 illustrates an arrangement of the first bridge patterns BRE1. The arrangement and configuration of the first bridge patterns BRE1 in the display device 10 may vary. For example, the arrangement, configuration, and number of first bridge patterns BRE1 may vary depending on both the arrangement, configuration, and number of second subpixel circuits SPC2 disposed in the first sub-display area SDA1 and the arrangement, configuration, and number of subpixel electrodes SAE in the second sub-display area SDA2.

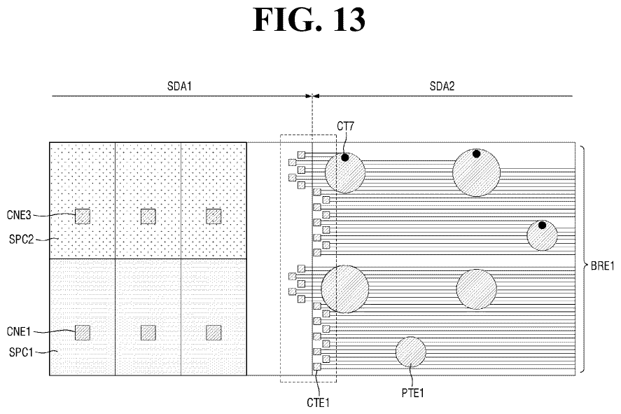

Referring to FIG. 13, first connection electrodes CNE1 of the first subpixel circuits SPC1 and third connection electrodes CNE3 of the second subpixel circuits SPC2 may be disposed in the first sub-display area SDA1. A plurality of first planarization patterns PTE1 may be disposed in the second sub-display area SDA2, and a plurality of first contact patterns CTE1 may be disposed near the boundary between the first and second sub-display areas SDA1 and SDA2. FIG. 13 illustrates the arrangement of the first connection electrodes CNE1, the third connection electrodes CNE3, the first contact patterns CTE1, and the first planarization patterns PTE1 of the fourth conductive layer CDL4.

The first connection electrodes CNE1 and the third connection electrodes CNE3 may be electrically connected to first transistors TFT1 of the first subpixel circuits SPC1 and first transistors TFT1 of the second subpixel circuits SPC2, respectively. As previously mentioned, the first connection electrodes CNE1 and the third connection electrodes CNE3 may contact the first active layer ACT1 of the first semiconductor layer SCL1.

The first contact patterns CTE1 may be disposed to overlap with the first bridge patterns BRE1. The first contact patterns CTE1 may be disposed to correspond to and contact the first bridge patterns BRE1. The first contact patterns CTE1 may be disposed to overlap with the ends of the first bridge patterns BRE1 positioned near the boundary between two different sub-display areas, i.e., the boundary between the first and second sub-display areas SDA1 and SDA2.

The first planarization patterns PTE1 may be disposed in the second sub-display area SDA2. The first planarization patterns PTE1 may be spaced from one another, and the arrangement of the first planarization patterns PTE1 may correspond to the arrangement of the subpixel electrodes SAE and the copy pixel electrodes CPE. Some of the first planarization patterns PTE1 may be disposed to overlap with the subpixel electrodes SAE, while other first planarization patterns PTE1 may be disposed to overlap with the copy pixel electrodes CPE. The first planarization patterns PTE1 that overlap with the subpixel electrodes SAE may be disposed to overlap with and contact the first bridge patterns BRE1. For example, the first planarization patterns PTE1 may contact the first bridge patterns BRE1 through seventh contact holes CT7.

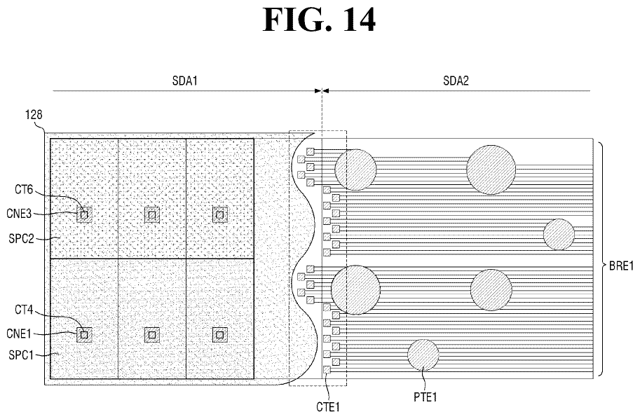

Referring to FIG. 14, the sixth insulating layer 128 may be disposed in the first sub-display area SDA1. The sixth insulating layer 128 may be disposed not to overlap with the first contact patterns CTE1 at the boundary between the first and second sub-display areas SDA1 and SDA2. As mentioned earlier, the sixth insulating layer 128 may include an organic insulating material and may not be disposed in the second sub-display area SDA2 in consideration of the light transmittance of the second sub-display area SDA2. In one or more embodiments, the sixth insulating layer 128 may be disposed in the entire main display area MDA.

The sixth insulating layer 128 may include a plurality of fourth contact holes CT4 and a plurality of sixth contact holes CT6, which penetrate the sixth insulating layer 128. The fourth contact holes CT4 may be formed to correspond to the first connection electrodes CNE1, and the sixth contact holes CT6 may be formed to correspond to the third connection electrodes CNE3.

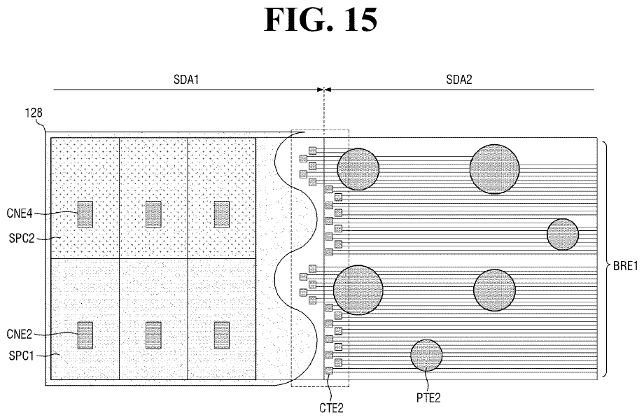

Referring to FIG. 15, second connection electrodes CNE2 of the first subpixel circuits SPC1 and fourth connection electrodes CNE4 of the second subpixel circuits SPC2 may be disposed in the first sub-display area SDA1. A plurality of second planarization patterns PTE2 may be disposed in the second sub-display area SDA2, and a plurality of second contact patterns CTE2 may be disposed near the boundary between the first and second sub-display areas SDA1 and SDA2. FIG. 15 illustrates the arrangement of the second connection electrodes CNE2, the fourth connection electrodes CNE4, the second contact patterns CTE2, and the second planarization patterns PTE2 of the fifth conductive layer CDL5.

The second connection electrodes CNE2 and the fourth connection electrodes CNE4 may be disposed to overlap with the first connection electrodes CNE1 and the third connection electrodes CNE3, respectively. The second connection electrodes CNE2 may contact the first connection electrodes CNE1 through the fourth contact holes CT4 formed in the sixth insulating layer 128, and the fourth connection electrodes CNE4 may contact the third connection electrodes CNE3 through the sixth contact holes CT6 formed in the sixth insulating layer 128.

The second contact patterns CTE2 and the second planarization patterns PTE2 may be disposed to correspond to the first contact patterns CTE1 and the first planarization patterns PTE1, respectively. The second contact patterns CTE2 may be formed to have a larger planar area than the first contact patterns CTE1 and thus to cover the outer surfaces (e.g., outer peripheral surfaces) of the first contact patterns CTE1. The second planarization patterns PTE2 may be formed to have a larger planar area than the first planarization patterns PTE1 and thus to cover the outer surfaces (e.g., outer peripheral surfaces) of the first planarization patterns PTE1. The first contact patterns CTE1 and the second contact patterns CTE2 may be paired up to serve as electrodes connecting the first bridge patterns BRE1 and the second bridge patterns BRE2 that will be described. Also, the first planarization patterns PTE1 and the second planarization patterns PTE2 may be paired up to serve as electrodes connecting the first bridge patterns BRE1 and the bridge electrodes BAE. Additionally, the planarization patterns PTE may be paired up to flatten the area where the subpixel electrodes SAE and the copy pixel electrodes CPE of the second sub-display area SDA2 are disposed.

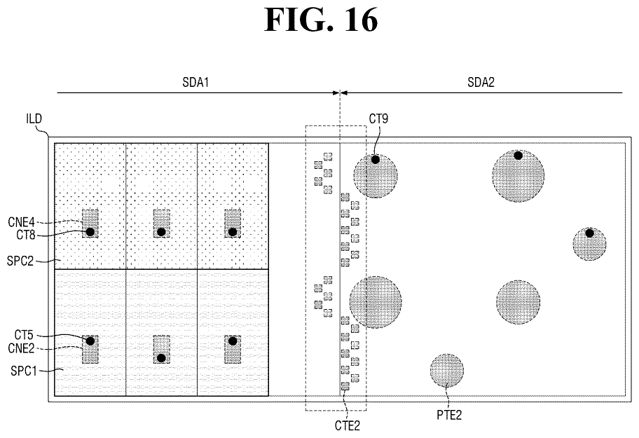

Referring to FIG. 16, the interlayer insulating layer ILD may be disposed across the first and second sub-display areas SDA1 and SDA2. The interlayer insulating layer ILD may serve as an inorganic via layer in the second sub-display area SDA2 where an organic insulating material is not disposed. In one or more embodiments, the interlayer insulating layer ILD may also be disposed in the main display area MDA.

The interlayer insulating layer ILD may include fifth contact holes CT5, which are formed to overlap with the second connection electrodes CNE2, and eighth contact holes CT8, which are formed to overlap with the fourth connection electrodes CNE4, in the first sub-display area SDA1. The interlayer insulating layer ILD may include ninth contact holes CT9, which are formed to overlap with some of the second planarization patterns PTE2, in the second sub-display area SDA2.

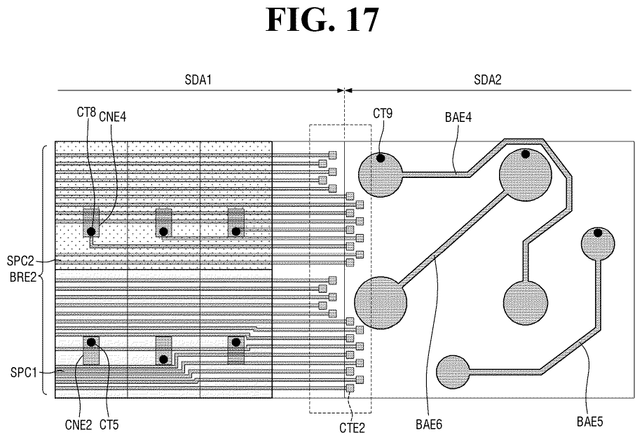

Referring to FIG. 17, a plurality of second bridge patterns BRE2 may be disposed in the first sub-display area SDA1. A plurality of bridge electrodes BAE, i.e., the fourth, fifth, and sixth bridge electrodes BAE4, BAE5, and BAE6, may be disposed in the second sub-display area SDA2.

The second bridge patterns BRE2 may be spaced from one another and may have an elongated shape in one direction. The second bridge patterns BRE2 may extend from the vicinity of the boundary between the first and second sub-display areas SDA1 and SDA2 toward the first sub-display area SDA1. First ends of the second bridge patterns BRE2 may overlap with and may be connected to the second contact patterns CTE2, and second ends of the second bridge patterns BRE2 may extend up to the fourth connection electrodes CNE4 of the first sub-display area SDA1. Some of the second bridge patterns BRE2 of FIG. 17 may extend to the fourth connection electrodes CNE4 of the second subpixel circuits SPC2 and may be connected to the fourth connection electrodes CNE4 through the eighth contact holes CT8. Other second bridge patterns BRE2 may be connected to the fourth connection electrodes CNE4 of other second subpixel circuits SPC2 not illustrated in FIG. 17. However, the second bridge patterns BRE2 may be disposed not to overlap with the fifth contact holes CT5, which are formed to overlap with the first subpixel circuits SPC1. The second bridge patterns BRE2, which extend in one direction, may be disposed to bypass the fifth contact holes CT5, and the subpixel electrodes SAE may be connected to the second connection electrodes CNE2 through the fifth contact holes CT5. The second subpixel circuits SPC2 may be electrically connected to the second bridge patterns BRE2, the contact patterns CTE, the first bridge patterns BRE1, and the planarization patterns PTE. The second bridge patterns BRE2, the contact patterns CTE, the first bridge patterns BRE1, and the planarization patterns PTE may serve as paths for transmitting emission signals applied from the second subpixel circuits SPC2.

FIG. 17 illustrates an arrangement of the second bridge patterns BRE2. The arrangement and layout of the second bridge patterns BRE2 In the display device 10 may be variably modified. For example, the arrangement, layout, and number of second bridge patterns BRE2 may vary depending on both the arrangement, layout, and number of second subpixel circuits SPC2 disposed in the first sub-display area SDA1, and the arrangement, layout, and number of subpixel electrodes SAE disposed in the second sub-display area SDA2.

Each of the fourth, fifth, and sixth bridge electrodes BAE4, BAE5, and BAE6 may be disposed to overlap with two different planarization patterns PTE. The fourth, fifth, and sixth bridge electrodes BAE4, BAE5, and BAE6 may include first portions disposed to overlap with the planarization patterns PTE and second portions connecting the first portions. Either the first portions or the second portions of the fourth, fifth, and sixth bridge electrodes BAE4, BAE5, and BAE6 may be connected to the planarization patterns PTE through the ninth contact holes CT9.

In one or more embodiments, the multiple second bridge patterns BRE2 and the fourth, fifth, and sixth bridge electrodes BAE4, BAE5, and BAE6, which are disposed in the second sub-display area SDA2, may include a TCO such as ITO or IZO.

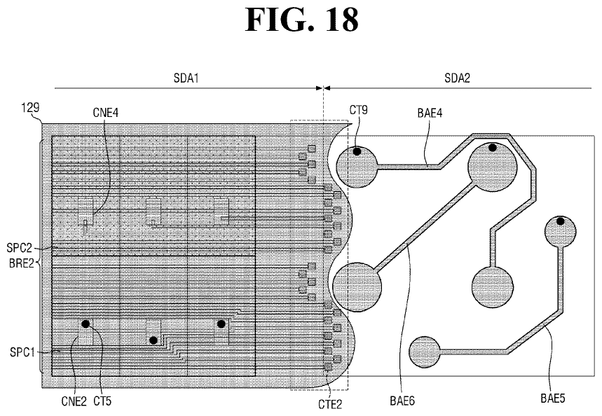

Referring to FIG. 18, the seventh insulating layer 129, like the sixth insulating layer 128, may be disposed in the first sub-display area SDA1 and also in part in the second sub-display area SDA2. The seventh insulating layer 129 may be disposed to cover the contact patterns CTE near the boundary between the first and second sub-display areas SDA1 and SDA2. However, the seventh insulating layer 129 may not overlap with the bridge electrodes BAE and the planarization patterns PTE, disposed in the second sub-display area SDA2. The seventh insulating layer 129 may include the fifth contact holes CT5, which are formed to penetrate the seventh insulating layer 129.

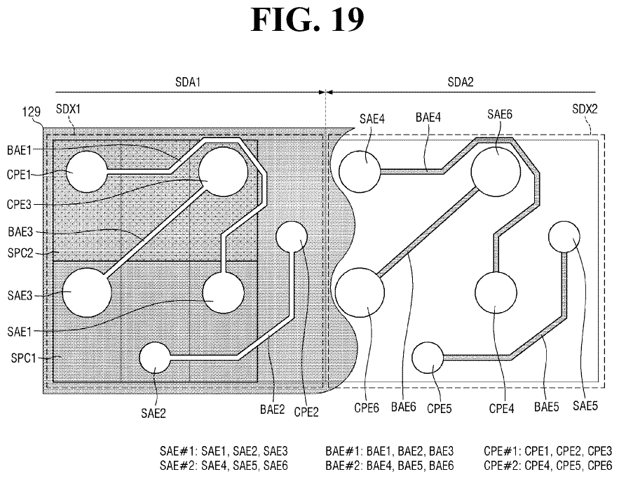

Referring to FIG. 19, the first, second, and third subpixel electrodes SAE1, SAE2, and SAE3, the first, second, and third copy pixel electrodes CPE1, CPE2, and CPE3, and the first, second, and third bridge electrodes BAE1, BAE2, and BAE3 may be disposed in the first sub-display area SDA1. The fourth, fifth, and sixth subpixel electrodes SAE4, SAE5, and SAE6 and the fourth, fifth, and sixth copy pixel electrodes CPE4, CPE5, and CPE6 may be disposed in the second sub-display area SDA2. The first, second, and third subpixel electrodes SAE1, SAE2, and SAE3, the first, second, and third copy pixel electrodes CPE1, CPE2, and CPE3, and the first, second, and third bridge electrodes BAE1, BAE2, and BAE3 of the first sub-display area SDA1 may be disposed on the seventh insulating layer 129, and the fourth, fifth, and sixth subpixel electrodes SAE4, SAE5, and SAE6 and the fourth, fifth, and sixth copy pixel electrodes CPE4, CPE5, and CPE6 of the second sub-display area SDA2 may be disposed on the fourth, fifth, and sixth bridge electrodes BAE4, BAE5, and BAE6.

The subpixel electrodes SAE, the copy pixel electrodes CPE, and the bridge electrodes BAE in the first sub-display area SDA1 may be integrated together to form single electrodes. For example, the first subpixel electrodes SAE1, the first bridge electrodes BAE1, and the first copy pixel electrodes CPE1 may be integrated together to form a single electrode. The first subpixel electrodes SAE1 may be disposed to overlap with the first subpixel circuits SPC1 and may be connected to the second connection electrodes CNE2 through the fifth contact holes CT5. The first copy pixel electrodes CPE1 may be integrated with the first bridge electrodes BAE1 and the first subpixel electrodes SAE1 and may be electrically connected to the second connection electrodes CNE2. The same light emission signals may be applied to pairs of subpixel electrodes SAE and copy pixel electrodes CPE disposed in the first sub-display area SDA1.

The subpixel electrodes SAE and the copy pixel electrodes CPE in the second sub-display area SDA2 may be disposed on the bridge electrodes BAE. For example, the fourth subpixel electrode SAE4 and the fourth copy pixel electrode CPE4 may be disposed on the first portion of the fourth bridge electrode BAE4 that is disposed on the planarization patterns PTE, and may directly contact the first portion of the fourth bridge electrode BAE4. The fourth bridge electrode BAE4 may be electrically connected to its corresponding second subpixel circuit SPC2 through the planarization patterns PTE, the bridge patterns (BRE1 and BRE2), and the contact patterns CTE. The fourth subpixel electrode SAE4 and the fourth copy pixel electrode CPE4 may be electrically connected to their corresponding second subpixel circuit SPC2 through the fourth bridge electrode BAE4. The same emission signals may be applied to pairs of subpixel electrodes SAE and copy pixel electrodes CPE disposed in the second sub-display area SDA2.

In one or more embodiments, the planarization patterns PTE disposed in the second sub-display area SDA2 may have a larger area than the first portions of the bridge electrodes BAE, the subpixel electrodes SAE, and the copy pixel electrodes CPE disposed thereon. For example, in one or more embodiments, the planarization patterns PTE may have a larger area than the fourth copy pixel electrode CPE4, and the first portion of the fourth bridge electrode BAE4 that they overlap with. Consequently, the top surfaces of the fourth subpixel electrode SAE4, the fourth copy pixel electrode CPE4, and the fourth bridge electrode BAE4 disposed on the planarization patterns PTE may be formed to be flat. The display device 10 can ensure the flatness of pixel electrodes, which serve as the anode electrodes of the light-emitting elements EL, through the planarization patterns PTE even if an organic insulating material for planarization is not disposed in the second sub-display area SDA2. Accordingly, light-emitting layers EML disposed on the pixel electrodes can be formed on a flat surface, preventing degradation caused by steps.

Moreover, patterns for connecting the second subpixel circuits SPC2 and the subpixel electrodes SAE disposed in the second sub-display area SDA2, such as the first bridge patterns BRE1, the contact patterns CTE, and the planarization patterns PTE, can be formed in (e.g., at) the same layer as the semiconductor layers or conductive layers for implementing pixel circuits in the main display area MDA and the first sub-display area SDA1. As a result, the advantage of not adding mask counts during the manufacture of the display device 10 can be provided.

Furthermore, In one or more embodiments, the first and second pixel-defining films 131 and 132, the light-emitting layers EML, and the common electrode CE may be disposed on the subpixel electrodes SAE and the copy pixel electrodes CPE. As mentioned earlier, the first pixel-defining film 131 may be disposed in the entire main display area MDA and the entire first sub-display area SDA1, but openings that expose portions of the subpixel electrodes SAE and portions of the copy pixel electrodes CPE may be formed in the first pixel-defining film 131. Additionally, as previously mentioned, the second pixel-defining film 132 may be disposed in the second sub-display area SDA2 to cover only the edges of the subpixel electrodes SAE and copy pixel electrodes CPE.

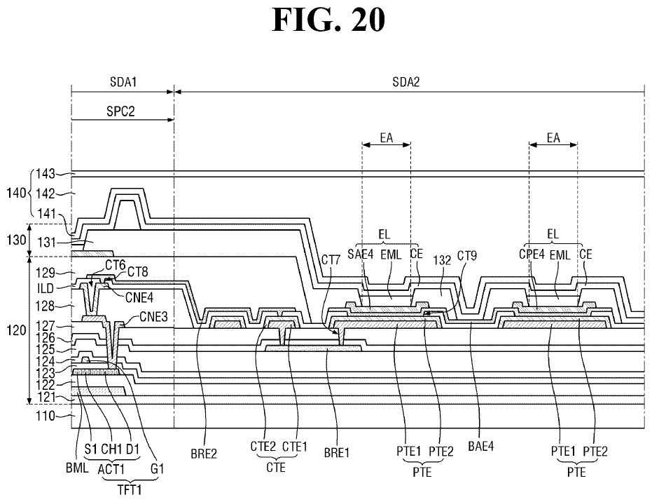

FIG. 20 is a cross-sectional view illustrating a sub-display area of a display device according to one or more embodiments of the present disclosure.

Referring to FIG. 20, an interlayer insulating layer ILD of a display device 10 may include a plurality of openings formed to correspond to planarization patterns PTE, in a second sub-display area SDA2. Bridge electrodes (BAE4, BAE5, and BAE6) may be disposed on the interlayer insulating layer ILD and may be positioned directly on the planarization patterns PTE through the openings. The embodiment of FIG. 20 differs from the embodiment of FIG. 11 in that the bridge electrodes (BAE4, BAE5, and BAE6) in the second sub-display area SDA2 are in contact with the planarization patterns PTE over larger areas through the openings, not through contact holes.

The display device 10 can ensure the flatness of subpixel electrodes SAE and copy pixel electrodes CPE, which serve as anode electrodes, through the planarization patterns PTE disposed in the second sub-display area SDA2. In one or more embodiments, if the planar area of the planarization patterns PTE is sufficiently large, openings may be formed in the interlayer insulating layer ILD to ensure flatness while concurrently (e.g., simultaneously) increasing the contact areas between bridge electrodes BAE and the planarization patterns PTE. The openings of the interlayer insulating layer ILD may be larger than the openings of a second pixel-defining film 132, and the second pixel-defining film 132 may cover portions on the subpixel electrodes SAE and copy pixel electrodes CPE that are stepped by the openings of the interlayer insulating layer ILD. Accordingly, at least portions of the subpixel electrodes SAE and copy pixel electrodes CPE that are exposed by the openings of the second pixel-defining film 132 can have flat surfaces, and light-emitting layers EML disposed on the exposed portions of the subpixel electrodes SAE and copy pixel electrodes CPE can be formed on the flat surfaces.

In concluding the detailed description, those skilled in the art will appreciate that many variations and modifications can be made to embodiments without substantially departing from the principles, spirit, and scope of the present disclosure. Therefore, the embodiments of the present disclosure are used in a generic and descriptive sense only and not for purposes of limitation.

What is claimed is:

1. A display device comprising:
a first sub-display area and a second sub-display area that are adjacent each other, and a main display area around the first and second sub-display areas;
a plurality of pixel electrodes in the main display area and spaced from one another;
a plurality of first subpixel electrodes in the first sub-display area and spaced from one another;
a plurality of first copy pixel electrodes in the first sub-display area and connected to the first subpixel electrodes through first bridge electrodes;
a plurality of planarization patterns in the second sub-display area;
a plurality of second subpixel electrodes and a plurality of second copy pixel electrodes in the second sub-display area that overlaps the planarization patterns; and
a plurality of second bridge electrodes that overlaps the second subpixel electrodes or the second copy pixel electrodes.

2. The display device of claim 1, wherein the first subpixel electrodes, the first copy pixel electrodes, and the first bridge electrodes, in the first sub-display area, are integrated together.

3. The display device of claim 1, wherein the second bridge electrodes overlap different planarization patterns.

4. The display device of claim 3, wherein each of the second bridge electrodes is in direct contact with one of the planarization patterns.

5. The display device of claim 1, wherein in a plan view, the planarization patterns have an area that is larger than both the second subpixel electrodes and the second copy pixel electrodes.

6. The display device of claim 1, wherein:
the planarization patterns comprise first planarization patterns and second planarization patterns that are located directly on the first planarization patterns; and
the second planarization patterns cover outer surfaces of the first planarization patterns.

7. The display device of claim 1, wherein further comprising:
a plurality of first bridge patterns extending in one direction in the second sub-display area;
a plurality of second bridge patterns extending in the one direction in the first sub-display area; and
a plurality of contact patterns overlapping the first bridge patterns and the second bridge patterns, near a boundary between the first and second sub-display areas.

8. The display device of claim 7, further comprising:
a plurality of first subpixel circuits and a plurality of second subpixel circuits in the main display area, wherein:
the first subpixel electrodes overlap the first subpixel circuits; and
at least some of the first copy pixel electrodes overlap the second subpixel circuits.

9. The display device of claim 8, wherein each of the second bridge patterns is electrically connected to one of the second subpixel circuits.

10. The display device of claim 7, wherein each of the first bridge patterns is connected to one of the planarization patterns.

11. The display device of claim 7, wherein each of the second bridge patterns overlaps the first subpixel electrodes, but is not connected to the first subpixel electrodes.

12. The display device of claim 7, further comprising:
a first insulating layer in the main display area and the first sub-display area and comprising an organic insulating material; and
an interlayer insulating layer on the first insulating layer, in the main display area and the first and second sub-display areas,
wherein the first insulating layer does not overlap the planarization patterns, the second subpixel electrodes, and the second copy pixel electrodes.

13. The display device of claim 12, wherein in the second sub-display area, the interlayer insulating layer overlaps the planarization patterns, the second subpixel electrodes, and the second copy pixel electrodes.

14. The display device of claim 12, wherein the first insulating layer overlaps the contact patterns.

15. The display device of claim 1, further comprising:
a first pixel-defining film in the main display area and the first sub-display area and having a plurality of openings that overlap the pixel electrodes, the first subpixel electrodes, and the first copy pixel electrodes; and
a second pixel-defining film in the second sub-display area covering edges of the second subpixel electrodes and edges of the second copy pixel electrodes.

16. A display device comprising:
a substrate having a first sub-display area and a second sub-display area that are adjacent each other, and a main display area around the first and second sub-display areas;
a semiconductor layer comprising a plurality of active layers on the substrate, in the main display area, and the first sub-display area, and a plurality of first bridge patterns in the second sub-display area;
a first insulating layer on the semiconductor layer;
a first conductive layer comprising a plurality of first connection electrodes on the first insulating layer, in the first sub-display area, and a plurality of first planarization patterns in the second sub-display area;
a second insulating layer on the first conductive layer, the second insulating layer not being in the second sub-display area;
a second conductive layer comprising a plurality of second connection electrodes on the second insulating layer, in the first sub-display area, and a plurality of second planarization patterns on the first planarization patterns, in the second sub-display area;
an interlayer insulating layer on the second conductive layer;
a plurality of second bridge patterns on the interlayer insulating layer, in the first sub-display area, and a plurality of bridge electrodes on the second planarization patterns, in the second sub-display area;
a third insulating layer on the interlayer insulating layer and the second bridge patterns, in the main display area and the first sub-display area;
a plurality of pixel electrodes on the third insulating layer, in the main display area;
a plurality of first subpixel electrodes and a plurality of first copy pixel electrodes on the third insulating layer, in the first sub-display area; and
a plurality of second subpixel electrodes and a plurality of second copy pixel electrodes on the bridge electrodes, in the second sub-display area.

17. The display device of claim 16, wherein:
the bridge electrodes comprise first portions that are on different second planarization patterns and second portions that connect the first portions; and
the second subpixel electrodes and the second copy pixel electrodes are respectively on different first portions of the bridge electrodes.

18. The display device of claim 16, wherein a width of the second planarization patterns is greater than widths of the second subpixel electrodes and the second copy pixel electrodes.

19. The display device of claim 16, wherein:
the first connection electrodes and the second connection electrodes are electrically connected to the first subpixel electrodes; and
the first copy pixel electrodes are integrated with the first subpixel electrodes.

20. The display device of claim 16, wherein the semiconductor layer comprises a first semiconductor layer comprising a first active layer, and a second semiconductor layer comprises a second active layer and located between the first semiconductor layer and the first insulating layer, and the first bridge patterns.
